(19) United States
(12) Patent Application Publication
(10) Pub. No.: US 2022/0254785 A1
(43) Pub. Date: Aug. 11, 2022

(54) Electrical Contact Structure

(71) Applicant: Fujian Jinhua Integrated Circuit Co., Ltd., Jinjiang Quanzhou, Fujian (CN)

(72) Inventors: Huixian LAI, Jinjiang Quanzhou, Fujian (CN); Yu-Cheng TUNG, Jinjiang Quanzhou, Fujian (CN); Chao-Wei LIN, Jinjiang Quanzhou, Fujian (CN); Chia-Yi CHU, Jinjiang Quanzhou, Fujian (CN); Chien-Hung LU, Jinjiang Quanzhou, Fujian (CN)

(21) Appl. No.: 17/612,231

(22) PCT Filed: Mar. 17, 2020
(86) PCT No.: PCT/CN2020/079581

§ 371 Date: Nov. 18, 2021

(30) Foreign Application Priority Data
Sep. 27, 2019 (CN) 2019 10925253.2
Sep. 27, 2019 (CN) 2019 10927008.5

(51) Int. Cl. H01L 27/108

(52) U.S. Cl. CPC H01L 27/10855; H01L 27/10814; H01L 27/10897; H01L 27/10876; H01L 27/10888; H01L 27/10891; H01L 27/10885

(57) ABSTRACT

Provided are an electrical contact structure. Through enabling at least the first contact plug closest to a peripheral area to be formed above an isolation structure of a boundary area between a core area and the peripheral area and in contact with the isolation structure, and enabling a bottom portion of the first contact plug to be completely overlapped on the isolation structure, or, enabling a part of the bottom portion to be overlapped with the isolation structure, enabling the other part of the bottom portion to be overlapped with an active area (AA) of the core area next to the isolation structure, and even enabling a top portion of the first contact plug to be at least connected with a top portion of the contact plug above the AA of the core area next to the isolation structure.

### CROSS-REFERENCE TO RELATED APPLICATIONS

The present disclosure claims priority to Chinese Patent Application No. 201910927008.5 and Chinese Patent Application No. 201910925253.2, submitted to the State Intellectual Property Office (SIPO) on Sep. 27, 2019, the contents of which are hereby incorporated by reference in their entirety.

### TECHNICAL FIELD

The disclosure relates to the technical field of semiconductors, and in particular to an electrical contact structure.

### BACKGROUND

Various technologies are used to integrate more circuit patterns in a limited area of a semiconductor substrate or a wafer. Due to different distances between the circuit patterns, an integrated circuit is generally divided into a device dense area (Dense), a device sparse area (ISO) and a device isolated area, the device dense area is an area with a higher device density (namely the device is denser), the device sparse area is an area with a lower device density (namely the device is sparser), and the device isolated area is an area which is separately set relative to the sparse area and the dense area. Along with the continuous decrease of a critical dimension of a semiconductor device, the density of the circuit patterns and/or a device height are also increased continuously, subjected to the influence of a resolution limit of an optical exposure tool and a density difference effect (namely a dense/sparse effect of the circuit patterns) between the device dense area and the device sparse area, the difficulty may also be increased a lot (for example, a process margin is reduced) while a photolithography process and/or an etching process is performed, so that the performance of the semiconductor device manufactured is affected.

For example, in the case of a Dynamic Random Access Memory (hereinafter referred to as DRAM) device, a huge number of memory cells are gathered to form a memory array core area, and there is a peripheral area beside the core area, the peripheral area contains other transistor elements and contact structures and the like, the memory array core area is used as the device dense area of the DRAM to store data, and the peripheral area is used as the device sparse area of the DRAM to provide input-output signals and the like required by the memory array core area. Each memory cell in the memory array core area can be formed by a Metal Oxide Semiconductor (MOS) transistor and a capacitor connected serially. The capacitor is located in the memory array core area, the capacitor is stacked above a Bit Line (BL) and is electrically coupled to a storage node contact portion corresponding to the capacitor, and the storage node contact portion is electrically coupled to an Active Area (AA) below it. Along with the continuous development of semiconductor technologies, the critical dimension of the device is decreased continuously, and a gap between the memory cells of the DRAM device becomes narrower. While the storage node contact portion is formed by a Self Aligned Contact (SAC) process, subjected to the influence of the resolution limit of the optical exposure tool and the density difference effect between the device dense area and the device sparse area, a contact hole in an outermost side of a boundary of the memory array core area easily generates abnormality, so that a contact area between the capacitor formed above it and a contact plug in the contact hole is reduced, a contact impedance is increased, and even a problem that the capacitor at the outermost side of the boundary of the memory array area is collapsed is caused, the improvement of the DRAM performance is affected and limited by these problems.

### SUMMARY

The disclosure provides an electrical contact structure of a semiconductor device, the semiconductor device includes a substrate, the substrate includes a core area, a peripheral area and a boundary area located between the core area and the peripheral area, an isolation structure is formed in the boundary area, multiple core elements are formed in the core area, each of the core elements includes an active area (AA), the electrical contact structure includes:

multiple contact plugs, formed above the core area and the isolation structure;

and the multiple contact plugs include a first contact plug closest to the peripheral area, at least the first contact plug is formed above the isolation structure and in contact with the isolation structure, and the rest contact plugs are formed above each of the core elements in the core area and a bottom portion of each of the rest contact plugs is in contact with the AA of a corresponding core element.

Based on the same inventive concept, the disclosure further provides a semiconductor device, including:

a substrate, the substrate includes a core area, a peripheral area and a boundary area located between the core area and the peripheral area, an isolation structure is formed in the boundary area, multiple core elements are formed in the core area, and each of the core elements includes an AA;

an interlayer dielectric layer, covering the substrate; and

an electrical contact structure as mentioned above, the electrical contact structure is formed in the interlayer dielectric layer.

Based on the same inventive concept, the disclosure further provides a manufacturing method for the electrical contact structure of the semiconductor device as described in the disclosure, including:

a substrate is provided, the substrate includes a core area, a peripheral area and a boundary area located between the core area and the peripheral area, an isolation structure is formed in the boundary area, multiple core elements are formed in the core area, and each of the multiple core elements includes an active area (AA);

an interlayer dielectric layer is formed on the substrate, and multiple contact holes are formed in the interlayer dielectric layer, the multiple contact holes include a first contact hole closest to the peripheral area, at least the first contact hole passes through the interlayer dielectric layer and exposes the isolation structure partially, each of the rest contact holes pass through the interlayer dielectric layer and exposes the AA of a corresponding core element; and

a corresponding contact plug is formed in each of the contact holes.

Based on the same inventive concept, the disclosure further provides a manufacturing method for the semiconductor device, including: the manufacturing method for the electrical contact structure of the semiconductor device as described in the disclosure is used to form a corresponding electrical contact structure on a semiconductor substrate having a core area, a peripheral area and an isolation structure.

Compared with the related art, a technical scheme of the disclosure has the following beneficial effects.

Through enabling at least the first contact plug closest to the peripheral area to be formed above the isolation structure of the boundary area between the core area and the peripheral area and in contact with the isolation structure, and enabling the first contact plug to be integrally overlapped with the isolation structure, or enabling a part of a bottom portion of the first contact plug to be overlapped with the isolation structure, enabling the other part of the bottom portion to be overlapped with the AA of the core area next to the isolation structure, and even further enabling a top portion of the first contact plug to be at least connected with a top portion of the contact plug above the AA of the core area next to the isolation structure, while the first contact plug is integrally overlapped with the isolation structure, the electrical structure originally formed at the outermost side of the boundary of the core area is completely formed above the isolation structure in the boundary area and served as a virtual structure, thereby the consistency of the electrical structures connected to the contact plugs in the boundary and interior of the core area is guaranteed by the virtual structure. While a part of the bottom portion of the first contact plug is overlapped with the isolation structure, and the other part of the bottom portion is overlapped with the AA of the core area next to the isolation structure, and/or the top portion of the first contact plug is connected with the top portion of at least one contact plug in the core area, a cross sectional area of the top portion of the first contact plug is relatively increased, on the one hand, a sufficient process margin is provided for a subsequent process of forming the electrical structure above the first contact plug, it is beneficial to increase a size of the electrical structure in the boundary area, and avoid abnormality or collapse of the electrical structure in the boundary area; and on the other hand, there is a larger contact area between the electrical structure formed above the first contact plug and the first contact plug, thereby a contact impedance is reduced, and it is beneficial to improve the electrical performance of the device; and it is more important that the size of the electrical structure connected to the first contact plug is increased by the first contact plug, and a density difference of the circuit patterns between the core area and the peripheral area is reduce thereby in a photolithography process and/or an etching process of forming all of the electrical structures in the core area, the optical proximity effect can be improved, the sparse/dense load effect is reduced, the consistency of the electrical structures above the contact plugs in the core area is guaranteed, and the device performance is improved. In addition, because at least part of the first contact plug is located in the boundary area, on the one hand, an occupied area of the core area by the first contact plug and the electrical structure connected to it (an area of the electrical structure can be reduced to a small size) can be reduced as much as possible, it is beneficial to improve an effective area utilization rate of the core area, and it is beneficial to improve the device density; and on the other hand, the sizes of the first contact plug and the electrical structure connected to it can be increased as much as possible, so that it has the better effects in aspects such as the consistency between the electrical structures connected to all of the contact plugs in the interior of the core area is improved.

Further, the disclosure further provides a mask plate combination, used for manufacturing a contact plug, the mask plate combination includes:

a first mask plate, having multiple parallel first light-shielding strips, and a first light-transmitting area formed between two neighboring first light-shielding strips;

a second mask plate, having multiple parallel second light-shielding strips, and a second light-transmitting area formed between two neighboring second light-shielding strips; and

a third mask plate, having a light-shielding block and a third light-transmitting area complementary to the light-shielding block.

While the first mask plate, the second mask plate and the third mask plate are successively superposed together, the multiple parallel second light-shielding strips are intersected with each of the multiple parallel first light-shielding strips, the light-shielding block covers at least one first light-shielding strip closest to a boundary of the first mask plate and a part of the first light-transmitting area nearest to a covered first light-shielding strip, and the light-shielding block also covers at least two second light-shielding strips closest to a boundary of the second mask plate and a part of the second light-transmitting area between two covered second light-shielding strips, an overlapping area of the third light-transmitting area, the first light-transmitting area and the second light-transmitting area is an area for forming the contact plug.

Based on the same inventive concept, the disclosure further provides a manufacturing method of a contact plug, the mask plate combination of the disclosure is used for manufacturing, and the contact plug manufacturing method includes:

a semiconductor substrate in which multiple active areas are formed is provided, and an interlayer dielectric layer and a first mask layer are successively formed on the semiconductor substrate;

a process of photolithography combined with etching is used to transfer a pattern on the first mask plate in the mask plate combination to the first mask layer so as to obtain a transferred first mask layer, and multiple first lines are formed in the transferred first mask layer, each of the multiple first lines corresponds to a corresponding first light-shielding strip on the first mask plate, a groove between the neighboring first lines corresponds to a corresponding first light-transmitting area on the first mask plate and exposes a corresponding area of the interlayer dielectric layer;

the interlayer dielectric layer and the first mask layer are covered by a second mask layer, and a process of photolithography combined with etching is used to transfer a pattern on the second mask plate in the mask plate combination to the second mask layer so as to obtain a transferred second mask layer, multiple second lines are formed in the transferred second mask layer, the multiple second lines are intersected with each of the multiple first lines, each of the multiple second lines corresponds to a corresponding second light-shielding strip on the second mask plate, a groove between the neighboring second lines corresponds to a corresponding second light-transmitting area on the second mask plate and exposes a corresponding first line and the interlayer dielectric layer in the first light-transmitting area;

the first mask layer, the second mask layer and the interlayer dielectric layer are covered by the third mask layer, and a process of photolithography combined with etching is used to transfer a pattern on the third mask plate in the mask plate combination to the third mask layer so as to obtain a transferred third mask layer, the transferred third mask layer corresponds to a light-shielding block of the third mask plate, the interlayer dielectric layer jointly exposed by the transferred third mask layer, the transferred first mask layer and the transferred second mask layer is an area for forming the contact plug;

the transferred first mask layer, the transferred second mask layer and the transferred third mask layer are served as masks to etch an exposed area of the interlayer dielectric layer, as to form multiple contact holes for exposing the corresponding the active areas;

the contact plug is formed in each of the contact holes, and a bottom portion of each of the contact plugs is in contact with a corresponding active area.

Based on the same inventive concept, the disclosure further provides a manufacturing method for a semiconductor device, including: the method for manufacturing the contact plug of the disclosure is used to form contact plugs on a semiconductor substrate having a core area, and a bottom portion of each of the contact plugs is in contact with an AA of a corresponding core element in the core area.

Based on the same inventive concept, the disclosure further provides a semiconductor device manufactured by using the manufacturing method for the semiconductor device of the disclosure, including:

a semiconductor substrate, the semiconductor substrate includes a core area, multiple core elements are formed in the core area, and each of the multiple core elements includes an active area;

an interlayer dielectric layer, formed on the semiconductor substrate; and

multiple contact plugs, formed in the interlayer dielectric layer, and in contact with the active area of a corresponding core element;

there is no contact plug above a part of the AAs at a boundary of the core area.

### BRIEF DESCRIPTION OF THE DRAWINGS

FIGS. 1A to 1C are cross-sectional structure schematic diagrams of electrical contact structures of a semiconductor device in a specific embodiment of the disclosure.

FIGS. 2A to 2D are cross-sectional structure schematic diagrams in a manufacturing method of a specific embodiment of the electrical contact structure of the semiconductor device of FIG. 1C.

FIGS. 3A to 3D are cross-sectional structure schematic diagrams in a manufacturing process of another specific embodiment of the electrical contact structure of the semiconductor device of FIG. 1C.

FIG. 4 is a top view structure schematic diagram in a manufacturing process for a semiconductor device in an embodiment of the disclosure.

FIGS. 5 to 13 are cross-sectional structure schematic diagrams along a line aa′ in FIG. 4 in a manufacturing process for a semiconductor device in an embodiment of the disclosure.

FIG. 14 is a structure schematic diagram of a first mask plate in a specific embodiment of the disclosure.

FIG. 15 is a structure schematic diagram of a second mask plate in a specific embodiment of the disclosure.

FIG. 16 is a structure schematic diagram of a third mask plate in another specific embodiment of the disclosure.

FIG. 17A is a structure schematic diagram after the first mask plate is aligned and overlapped with a pattern of an AA of a core area (some layers that affect to observe a pattern alignment overlapping effect are omitted) in a specific embodiment of the disclosure.

FIG. 17B is a structure schematic diagram after the second mask plate, the first mask plate are aligned and overlapped with the pattern of the AA of the core area (some layers that affect to observe the pattern alignment overlapping effect are omitted). in a specific embodiment of the disclosure

FIG. 17C is a structure schematic diagram after the third mask plate, the second mask plate and the first mask plate are aligned and overlapped with the pattern of the AA of the core area (some layers that affect to observe the pattern alignment overlapping effect are omitted) in the specific embodiment of the disclosure.

FIG. 18 is a distribution schematic diagram of contact plugs manufactured in the core area by using a mask plate combination in a specific embodiment of the disclosure, there is no contact plug above a part of the AAs at the boundary of the core area.

FIG. 19 is a cross-sectional structure schematic diagram along the line aa′ and at the boundary of the core area in FIG. 18 in a specific embodiment of the disclosure.

FIG. 20 is a cross-sectional structure schematic diagram of a semiconductor device at the boundary of the core area in a specific embodiment of the disclosure.

Reference signs are described as follows.
I—Core area; II—Peripheral area; III—Boundary area; H1 and H2—Depth; AA1 and AA2—Active area; WL—Buried-type word line; BL—Bit line; S/D1 and S/D2—Source area and Drain area; G1—Gate electrode structure; W1—First width; W2—Second width;
100—Substrate; 100a and 100b—Isolation structure; 101—Active area; 102—Interlayer dielectric layer; 102a, 102b and 102c—Contact hole; 102d—Groove; 103a, 103b and 103c—Contact plug; 104—First mask pattern; 105—Sacrificial layer; 106—Second mask pattern; 107—Second interlayer dielectric layer; 107a, 107b and 107c—Groove; 180—Second mask pattern; 109a, 109b and 109c—Contact pad; 300—Semiconductor substrate; 300a—Semiconductor base; 301a and 301b—Shallow groove isolation structure; 302—Gate electrode covering layer; 303—Etching stop layer; 304—Side wall; 400—Interlayer dielectric layer; 401a, 401b, 401d and 401e—Contact hole; 401c—Groove; 402—Sacrificial layer; 501a, 501d and 501e—Contact plug; 501b—Combined contact structure; 600—Bottom support layer; 601—Intermediate support layer; 602—Top support layer; 611—First sacrificial layer; 612—Second sacrificial layer; 700a and 700b—Capacitance hole; 701—Bottom electrode layer; 702—Capacitance dielectric layer; 703—Top electrode layer; 704—Top electrode filling layer; 705a and 705b—Capacitor;
K1—First width; K2—Second width; P1—First mask layer; P10, P11 and P12—First line; P2—Second mask layer; P20—Second line; CTa—Groove; CP—Contact plug; P3—Third mask layer;
10—First mask plate; 111a, 111b and 111c—First light-shielding strip; 112—First light-transmitting area; 20—Second mask plate; 201—Second light-shielding strip; 202—Second light-transmitting area; 30—Third mask plate; 311—Light-shielding block; 312—Third light-transmitting area; 410—Semiconductor substrate; 410a—Semiconductor base; 411a and 411b—Shallow groove isolation structure; 412—Gate electrode covering layer; 413—Etching stop layer; and 500—Interlayer dielectric layer.

### DETAILED DESCRIPTION OF THE EMBODIMENTS

An electrical contact structure, a mask plate combination, a manufacturing method of a contact plug, a semiconductor device and a manufacturing method of the semiconductor device provided by the disclosure are further described in detail below in combination with drawings and specific embodiments. According to the following description, advantages and features of the disclosure are clearer. It is to be noted that the drawings are in a very simplified form and all use an imprecise proportion, and are only used to conveniently and clearly assist to describe purposes of the embodiments of the disclosure.

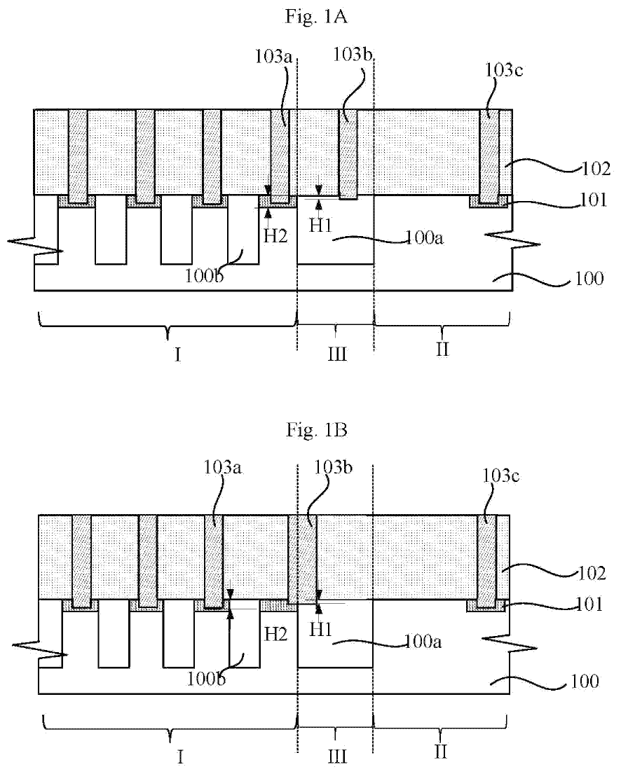

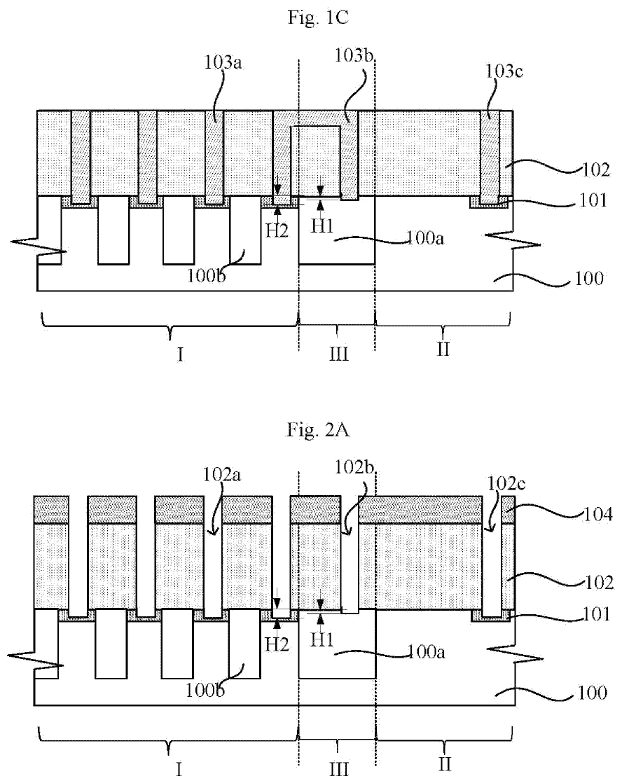

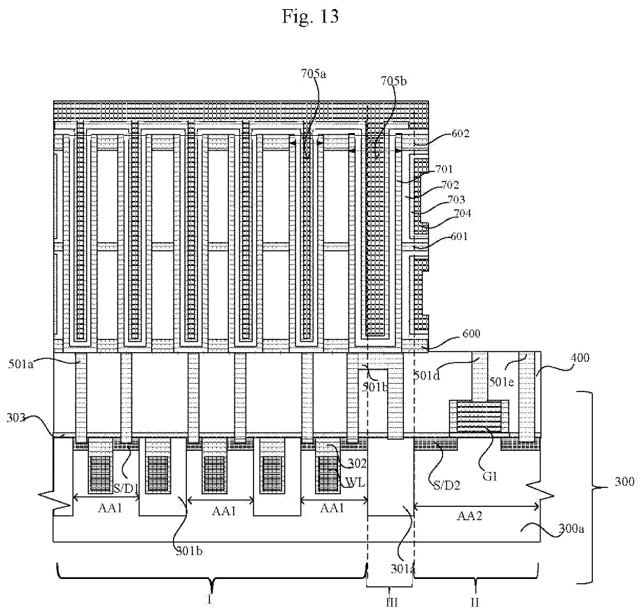

FIG. 1A shows a cross-sectional schematic diagram of an electrical contact structure of a semiconductor device in an embodiment of the disclosure. Please refer to FIG. 1A, the electrical contact structure of the semiconductor device provided by an embodiment of the disclosure includes: a substrate 100 and multiple contact plugs 103a and 103b. The substrate 100 includes a core area I, a peripheral area II and a boundary area III (also called as an interface place) located between the core area I and the peripheral area II, an isolation structure 100a is formed in the boundary area III, the core area I is a device dense area, and the peripheral area II surrounding it is a device sparse area. The multiple contact plugs 103a and 103b are formed above the core area I and the isolation structure 100a of the boundary area III, and at least the first contact plug 103b closest to the peripheral area II is formed above the isolation structure 100a of the boundary area III, and a bottom portion of the first contact plug 103b is in contact with the isolation structure 100a of the boundary area III, the rest contact plugs 103a are formed above core elements (unshown) of the core area I, and a bottom portion of each of the rest contact plugs 103a is in contact with the AA 101 of a corresponding core elements. Each of the contact plugs 103a and 103b can include a blocking metal layer (unshown) and a metal layer (unshown), the blocking metal layer may include, for example, Ti, Ta, Mo, TiₓN_{y}, TaₓN_{y}, TiₓZr_{y}, TiₓZr_{y}N_{z}, NbₓN_{y}, ZrₓN_{y}, WₓN_{y}, VₓN_{y}, HfₓN_{y}, MoₓN_{y}, RuₓN_{y} and/or TiₓSi_{y}N_{z}. The metal layer may include, for example, tungsten, copper and/or aluminum. Each of the contact plugs 103a can also include a metal silicide, as to reduce a contact resistance between it and the AA 101. In the present embodiment, a bottom portion of the first contact plug 103b is completely overlapped on the isolation structure 100a of the boundary area III, and the bottom portion of the first contact plug 103b can be stretched into the interior of the isolation structure 100a of the boundary area III, optionally, a depth H1 of the bottom portion of the first contact plug 103b stretched into the interior of the isolation structure 100a of the boundary area III is less than depths H2 of the bottom portions of the rest contact plugs 103a (namely the contact plug 103a in the core area I) stretched into the corresponding AAs 101. In the embodiment as shown in FIG. 1A, the first contact plug 103b on the isolation structure 100a of the boundary area III is integrally overlapped on the isolation structure 100a, thus, an electrical structure (unshown, may refer to a capacitor in FIG. 13) originally formed at an outermost side of a boundary of the core area I can be completely formed above the isolation structure 100a of the boundary area III and served as a virtual structure, thereby the consistency of the electrical structure connected to each of the contact plugs 103a in the core area I is guaranteed by the virtual structure.

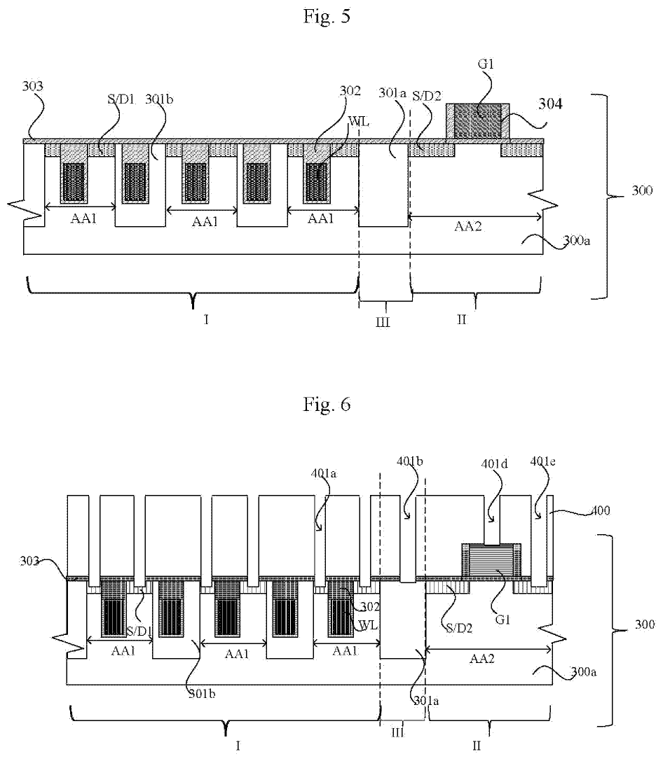

FIG. 1B shows a cross-sectional schematic diagram of an electrical contact structure of a semiconductor device in another embodiment of the disclosure. Please refer to FIG. 1B, the electrical contact structure of the semiconductor device provided by another embodiment of the disclosure includes: a substrate 100 and multiple contact plugs 103a and 103b. The substrate 100 has a core area I, a peripheral area II and a boundary area III located between the core area I and the peripheral area II, an isolation structure 100a is formed in the boundary area III, the core area I is a device dense area, and the peripheral area II surrounding it is a device sparse area. The multiple contact plugs 103a and 103b are formed above the core area I and the isolation structure 100a of the boundary area III, and at least the first contact plug 103b closest to the peripheral area II is formed above the isolation structure 100a of the boundary area III and an AA 101 of the isolation structure 100a next to the boundary area III in the core area I, and a part of a bottom portion of the first contact plug 103b is in contact and overlapped with the isolation structure 100a of the boundary area III, and the other part of the bottom portion of the first contact plug 103b is in contact and overlapped with the AA 101 of the isolation structure 100a next to the boundary area III in the core area I. A difference between the first contact plug 103b in the present embodiment and the first contact plug 103b in the embodiment as shown in FIG. 1A is that the bottom portion of the first contact plug 103b in the present embodiment is always crosswise extended from the isolation structure 100a of the boundary area III to the AA 101 of the core area I of the isolation structure 100a next to the boundary area III, and the bottom portion of the first contact plug 103b can be stretched into the interiors of the isolation structure 100a of the boundary area III and the corresponding AA 101. Optionally, the depth H1 of the bottom portion of the first contact plug 103b stretched into the interior of the isolation structure 100a of the boundary area III is less than the depths H2 of the bottom portions of the rest contact plugs 103a (namely the contact plug 103a in the core area I) stretched into the corresponding AAs 101. While a gate electrode (unshown, may refer to a buried-type word line in FIG. 5) buried in the substrate 100 is formed in the substrate, only one side of the first contact plug 103b is in contact with the gate electrode nearest to it and buried in the substrate 100. In the embodiment as shown in FIG. 1B, a part of the bottom portion of the first contact plug 103b above the isolation structure 100a of the boundary area III is overlapped with the isolation structure 100a of the boundary area III, and the other part of the bottom portion is overlapped with the AA 101 of the core area I next to the isolation structure 100a of the boundary area III, therefore, a cross-sectional area of the first contact plug 103b above the isolation structure 100a of the boundary area III is relatively increased, on the one hand, a sufficient process margin is provided for a subsequent process of forming the electrical structure (unshown, can refer to the capacitor in FIG. 13) in the boundary area III, it is beneficial to increase a size of the electrical structure in the boundary area III, and avoid abnormality or collapse of the electrical structure connected to the first contact plug 103b in the boundary area III; and on the other hand, there is a larger contact area between the electrical structure connected to the first contact plug 103b in the boundary area III and the first contact plug 103b, thereby a contact impedance is reduced, and it is beneficial to improve the electrical performance of the device; and it is more important that the size of the electrical structure connected to the first contact plug is increased by the first contact plug 103b in the boundary area III, and a density difference of the circuit patterns between the core area I and the peripheral area II can be reduced, thereby in a photolithography process and/or an etching process of forming all of the electrical structures in the core area I, the optical proximity effect can be improved, the sparse/dense load effect is reduced, the consistency of the electrical structures above each of the contact plugs 103a in the core area I is guaranteed, and the device performance is improved.

FIG. 1C shows a cross-sectional schematic diagram of an electrical contact structure of a semiconductor device in another embodiment of the disclosure. Please refer to FIG. 1C, the electrical contact structure of the semiconductor device provided by another embodiment of the disclosure includes: a substrate 100 and multiple contact plugs 103a and 103b. The substrate 100 has a core area I, a peripheral area II and a boundary area III located between the core area I and the peripheral area II, an isolation structure 100a is formed in the boundary area III, the core area I is a device dense area, and the peripheral area II surrounding it is a device sparse area. The multiple contact plugs 103a and 103b are formed above the core area I and the isolation structure 100a of the boundary area III, and at least the first contact plug 103b closest to the peripheral area II is formed above the isolation structure 100a of the boundary area III, a bottom portion thereof is completely overlapped on the isolation structure 100a of the boundary area III, and a top portion is at least connected with one contact plug 103a in an AA 101 next to the isolation structure 100a of the boundary area III in the core area I. A difference between the first contact plug 103b in the present embodiment and the first contact plug 103b in the embodiment as shown in FIG. 1A is that the top portion of the first contact plug 103b in the present embodiment is connected with the top portion of at least one contact plug 103a in the AA 101 of the core area I next to the isolation structure 100a of the boundary area III together. In the embodiment as shown in FIG. 1C, a top cross-sectional area of a combined contact structure formed while the top portions of the first contact plug 103b above the isolation structure 100a of the boundary area III and the at least one contact plug 103a are connected together is relatively increased, on the one hand, a sufficient process margin is provided for a subsequent process of forming the electrical structure (unshown, may refer to the capacitor in FIG. 13) in the boundary area III, it is beneficial to increase a size of the electrical structure in the boundary area III, and avoid abnormality or collapse of the electrical structure connected to the combined contact structure in the boundary area III; and on the other hand, there can be a larger contact area between the electrical structure connected to the combined contact structure in the boundary area III and the combined contact structure, thereby a contact impedance is reduced, and it is beneficial to improve the electrical performance of the device; and it is more important that the size of the electrical structure connected to the combined contact structure is increased by the combined contact structure in the boundary area III, and a density difference of the circuit patterns between the core area I and the peripheral area II can be reduced, thereby in a photolithography process and/or an etching process of forming all of the electrical structures in the core area I, the optical proximity effect can be improved, the sparse/dense load effect is reduced, the consistency of the electrical structures above each of the contact plugs 103a in the core area I is guaranteed, and the device performance is improved. All of the contact plugs 103b and 103a of which the top portions are connected together form an inverted U-shaped electrical contact structure or a comb-shaped electrical contact structure.

It is to be noted that in each of the above embodiments, the contact holes corresponding to the first contact plug 103b and each of the contact plugs 103a in the core area I are formed by the same etching process and the same filling process, as to simplify the process. In addition, a bottom portion of the contact hole corresponding to the contact plug 103a needs to expose the AA 101, and a bottom portion of the contact hole corresponding to the first contact plug 103b in the boundary area III needs to expose the isolation structure 100a, and a material of the isolation structure 100a is different from a material of the AA 101. While the corresponding contact holes are formed by etching at the same time, a speed of etching the isolation structure 100a is slower, and a speed of etching the AA 101 is faster, so that the depth H1 of the bottom portion of the first contact plug 103b in the boundary area III is less than the depths H2 of the bottom portions of the rest contact plugs 103a (namely the contact plug 103a in the core area) stretched into the corresponding AAs 101.

In addition, it is also to be noted that a corresponding isolation structure 100b is also formed between the AAs 101 of the neighboring core elements in the core area I, and used to define the AA 101 of each core element; and the isolation structure 100b and the corresponding contact plug 103c are also formed in the peripheral area II, the isolation structure 100b is used to define the AA 101 of each peripheral element.

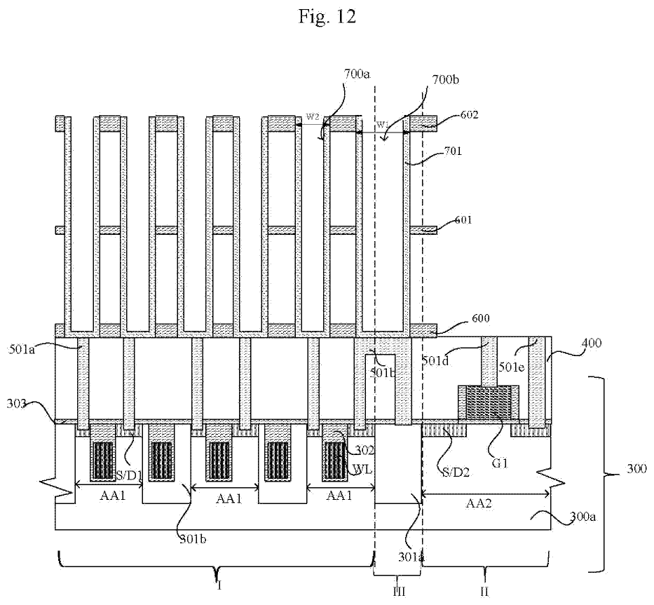

Please refer to FIG. 1A to 1C and FIG. 13, in the present embodiment, the semiconductor device is a DRAM, the core area is a memory array area of the DRAM, the core element is a memory transistor, the electrical contact structure is a storage node contact portion, connected to a capacitor (namely a storage node). Namely, each contact plug 103a in the core area I is connected to one capacitor (as shown in 705a of FIG. 12), the first contact plug 103b closest to the peripheral area II in all of the contact plugs of the core area I and the boundary III is connected to one capacitor (as shown in 705b of FIG. 12), and the capacitor of the boundary III has a first width W1, and the capacitor of the core area I has a second width W2. Optionally, the first width W1 is greater than the second width W2, on the one hand, the capacitor collapse in the boundary area III is avoided; and on the other hand, a size of the capacitor in the boundary area III is increased, a density difference of the circuit patterns between the core area I and the peripheral area II can be reduced, thereby while a photolithography process and/or an etching process is performed, the optical proximity effect can be improved, the sparse/dense load effect is reduced, the consistency of the capacitors above each of the contact plugs 103a in the core area is guaranteed, and problems that the capacitor above the contact plugs in some positions in the core area I is abnormal or the capacitor above the contact plug at the outermost side of the boundary of the core area I is collapsed are prevented. For example, W1=1.3*W2˜2.3*W2, as an example, W1=1.5*W2.

In addition, while the top portion of the first contact plug is not connected with the other contact plugs in the core area, the electrical structure connected to it can be served as a virtual structure, an area thereof is smaller, and it is better. Because the first contact plug is at least partially located on the isolation structure of the boundary area, the area of the electrical structure connected to it can be reduced to a small size, an occupied area thereof in the core area is reduced, and it is beneficial to improve an effective area utilization rate of the core area, thereby it is beneficial to improve the device density.

Please refer to FIG. 4, the semiconductor device includes multiple WLs and multiple BLs, each of the WLs is intersected with the multiple active areas AA1 in the core area I, the word line WL can be a buried-type word line, the BLs are formed above the core elements in the core area I and perpendicular to the word lines WL. While the structure of the first contact plug 103b closest to the peripheral area II in all of the contact plugs of the core area I and the boundary area III is a structure as shown in FIG. 1B, namely the first contact plug 103b is formed above the isolation structure 100a of the boundary area III and the AA 101 next to the isolation structure 100a of the boundary area III in the core area I, and a part of the bottom portion of the first contact plug 103b is in contact and overlapped with the isolation structure 100a of the boundary area III, and the other part of the bottom portion of the first contact plug 103b is in contact and overlapped with the AA 101 next to the isolation structure 100a of the boundary area III in the core area I, and only one side, towards the core area I, of the first contact plug 103b is in contact with the nearest WL thereof buried in the substrate 100. While the structure of the first contact plug 103b closest to the peripheral area II in all of the contact plugs of the core area I and the boundary area III is a structure as shown in FIG. 1C, namely the first contact plug 103b is formed above the isolation structure 100a of the boundary area III, and a top portion thereof is at least connected with a top portion of one contact plug 103a above the AA 101 next to the isolation structure 100a of the boundary area III in the core area I together, all of the contact plugs of which the top portions are connected together form an inverted U-shaped electrical contact structure or a comb-shaped electrical contact structure, and the inverted U-shaped electrical contact structure or the comb-shaped electrical contact structure can be in contact with the WL (namely the word line closest to the boundary area in the core area I) at the outermost boundary (namely the outermost side of the core area I) of the core area I and aligned with the BL (namely parallel), for example, one side, closest to the core area I, of the formed inverted U-shaped electrical contact structure or comb-shaped electrical contact structure is in contact with one WL in one AA1 at the outermost side of the core area I. It is to be noted that in the present embodiment, although the semiconductor device described as an example is the DRAM, the technical scheme of the disclosure is not limited to this, the semiconductor device may also be any suitable electrical devices, for example, a memory in other architectures, at this moment, the capacitor can be replaced with the corresponding electrical structure, for example, a resistor.

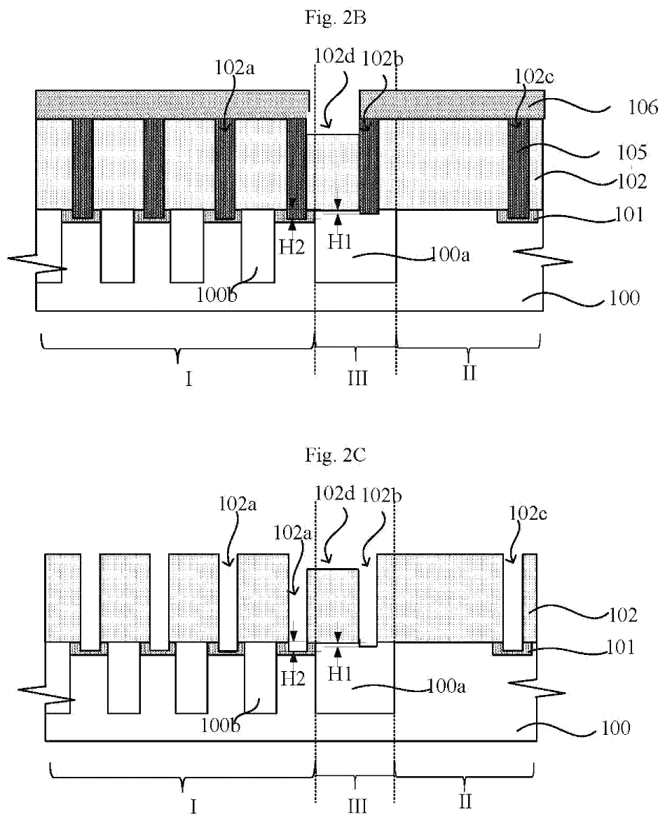

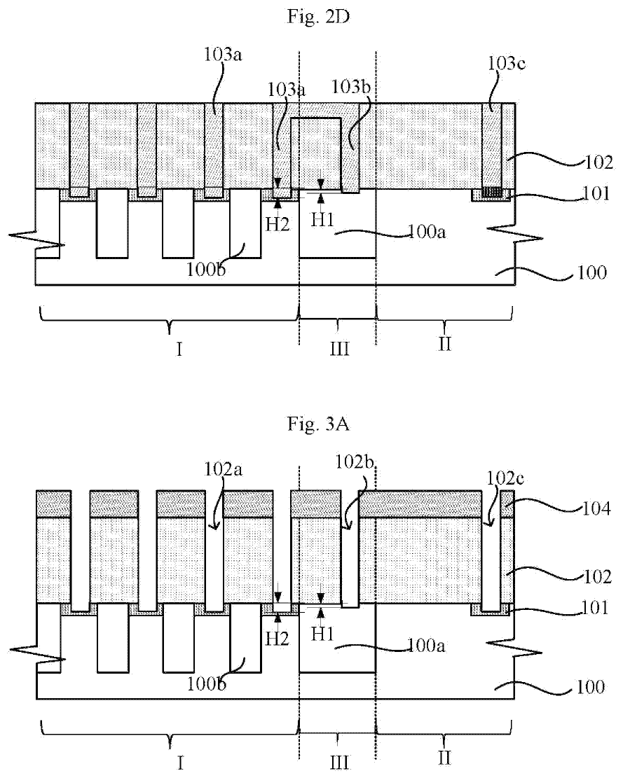

FIG. 2A to FIG. 2D show a device cross-sectional schematic diagram in a manufacturing process for the electrical contact structure of the semiconductor device as shown in FIG. 1C. Please refer to FIG. 2A to FIG. 2D, the present embodiment provides a manufacturing method for the electrical contact structure of the semiconductor device, including the following operations:

Firstly, please refer to FIG. 2A, a semiconductor substrate 100 is provided, the semiconductor substrate includes a core area I, a peripheral area II and a boundary area III located between the core area I and the peripheral area II, the semiconductor substrate 100 can be selected from a silicon base plate, a Silicon-On-Insulator (SOI) base plate, a germanium base plate, a germanium-on-insulator base plate (GOI), a silicon-germanium base plate and the like. Multiple shallow-groove isolation structures 100a and 100b are formed in the semiconductor substrate 100, the shallow-groove isolation structures 100a and 100b are formed in a mode of etching the semiconductor substrate 100 to form a groove, and filling the groove with an insulation material, a material of the shallow-groove isolation structures 100a and 100b may include a silicon oxide, a silicon nitride, or a silicon oxynitride and the like. The shallow-groove isolation structure 101a located in the boundary area III defines the boundary between the core area I and the peripheral area II on a two-dimensional plane, the shallow-groove isolation structure 100a located in the core area I defines the AA 101 corresponding to each core element in the core area I on a two-dimensional plane, and the shallow-groove isolation structure (unshown) located in the peripheral area II defines the AA 101 corresponding to each peripheral element in the peripheral area II on a two-dimensional plane.

Secondly, please continue to refer to FIG. 2A, the semiconductor substrate 100 is covered by an interlayer dielectric layer 102, and the interlayer dielectric layer 102 can be configured to have a single-layer structure or a multi-layer structure. The interlayer dielectric layer 102 may include at least one of a silicon nitride, a silicon oxynitride and a low-k dielectric material. A dielectric constant k of the low-k dielectric material is less than a dielectric constant of a silicon oxide, and it can be used as an Inter-Metallic Dielectric (IMD) layer, for example, a High-Density Plasma (HDP) oxide, Tetraethyl Orthosilicate (TEOS), Plasma-Enhanced TEOS (PE-TEOS), Undoped Silicate Glass (USG), Phospho-Silicate Glass (PSG), Boro-Silicate Glass (BSG), Boron-Phosphorous Silicate Glass (BPSG), Fluoride Silicate Glass (FSG), and Spin-On Glass (SOG). In addition, an etching stop layer (unshown) can be formed between the semiconductor substrate 100 and the interlayer dielectric layer 102, and the etching stop layer may include SiN, SiON, SiC, SiCN, BN (boron nitride) or any combinations thereof. The etching stop layer and the interlayer dielectric layer 102 can be formed by using Plasma-Enhanced Chemical Vapor Deposition (PECVD), High-Density Plasma CVD (HDP-CVD), Atmospheric Pressure CVD (APCVD) and/or spin-coating processes.

After that, please continue to refer to FIG. 2A, through a first photolithography process, a first mask pattern 104 is formed on the interlayer dielectric layer 102, and the first mask pattern 104 defines a position of each contact plug, after that, the first mask pattern 104 is used as an etching mask, the interlayer dielectric layer 102 is anisotropically etched to form contact holes 102a, 102b and 102c which pass through the interlayer dielectric layer 102 and expose the corresponding AAs 101 below, the contact holes 102a, 102b and 102c are mutually independent, each contact hole 102a is located in the core area I and exposes the AA 101 of the corresponding core element in the core area I, each contact hole 102b is located in the boundary area Ill and exposes the isolation structure 100a in the boundary area Ill, and each contact hole 102c is located in the peripheral area II and exposes the AA 101 of the corresponding peripheral element.

After that, please refer to FIG. 2B, after the contact holes 102a to 102c are formed, an ashing process or a wet-type cleaning process can be performed to remove the first mask pattern 104, and each of the contact holes 102a to 102c is filled with a sacrificial layer 105. The sacrificial layer 105 can be formed by a Spin-On Hard mask (SOH) layer or an Amorphous Carbon Layer (ACL), so that the contact holes 102a to 102c with a high depth-width ratio can be filled with the sacrificial layer 105.

Then, please continue to refer to FIG. 2B, a second mask pattern 106 can be formed on the interlayer dielectric layer 102 and the sacrificial layer 105 by a second photolithography process, and the second mask pattern 106 defines a groove 102d which is used for connecting the top portions of the contact hole 102b corresponding to the boundary area Ill and at least one contact hole 102a in the core area I next to the boundary area Ill. The second mask pattern 106 is served as a mask, and the interlayer dielectric layer at the boundary area Ill is etched, as to form the groove 102d which is used for connecting the top portions of the contact hole 102b corresponding to the boundary area Ill and at least one contact hole 102a in the core area I next to the boundary area Ill, the groove 102d is extended from the boundary area III to the core area I, and the groove 102d at least exposes one contact hole 102b of the boundary area III and one contact hole 102a at the outermost side of the core area I next to the boundary area III.

Please refer to FIG. 2D, the sacrificial layer 105 and the second mask pattern 106 in the contact holes 102a-102c and the groove 102d can be removed by using oxygen, ozone or ultraviolet ashing process or wet-type cleaning process, as to expose each of the contact holes 102a-102c and the groove 102d again.

Please continue to refer to FIG. 2D, a blocking metal layer (unshown) can be formed in the contact holes 102a-102c and the groove 102d, for example, the blocking metal layer may cover inner walls of the contact holes and the groove and a top surface of the interlayer dielectric layer 102 in a uniform thickness. The blocking metal layer may reduce or prevent a metal material installed in the contact hole and the groove from being diffused into the interlayer dielectric layer 102. For example, the blocking metal layer can be formed by Ta, TaN, TaSiN, Ti, TiN, TiSiN, W, WN or any combinations thereof, and can be formed by using processes such as the CVD, Atomic Layer Deposition (ALD) or Physical Vapor deposition (PVD) (for example, sputtering). After that, each of the contact holes 102a-102c and the groove 102d is filled with a metal layer, as to form contact plugs 103a, 103b and 103c. The metal layer can be formed by (one or more) refractory metal (for example, cobalt, iron, nickel, tungsten and/or molybdenum). In addition, the metal layer can be formed by using a deposition process with a good stepped covering property, for example, the metal layer can be formed by using the CVD, the ALD or the PVD (for example, sputtering). The metal layer formed by the deposition also covers a surface of the interlayer dielectric layer 102 around the contact holes, after that, chemical-mechanical polishing can be performed on a top surface of the deposited metal layer by using a Chemical-Mechanical Polishing (CMP) process, until the top surface of the interlayer dielectric layer 102 is exposed, as to form the contact plugs 103a, 103b and 103c located in the interlayer dielectric layer 102. At this moment, the contact plug 103b is the first contact plug closest to the peripheral area II in the core area I and the boundary area III, and a top portion thereof is connected with at least one contact plug 103a in the nearest neighboring core area I together, as to form an inverted U-shaped contact plug or a comb-shaped contact plug.

The method as shown in FIG. 2A to FIG. 2D is capable of, under the same number of lithography times, reducing times of the deposition process, and integrally forming all of the contact plugs of which the top portions are connected together.

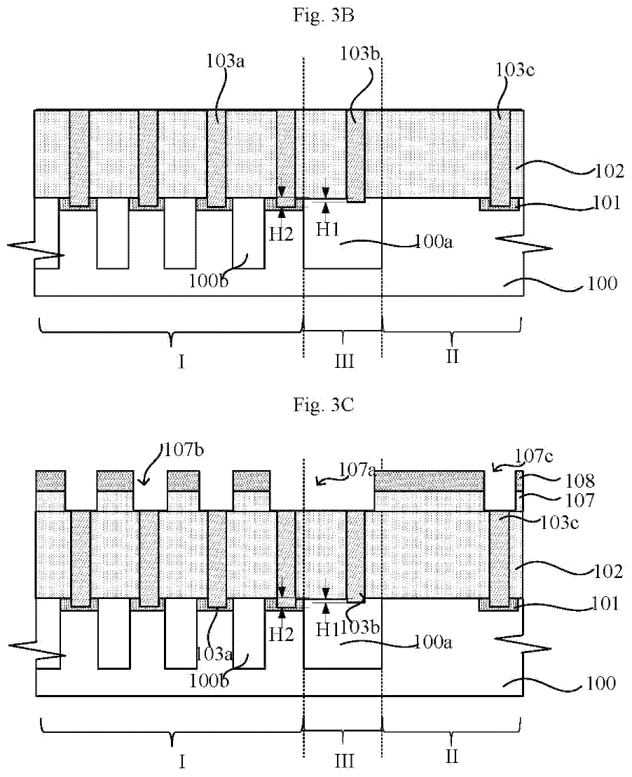

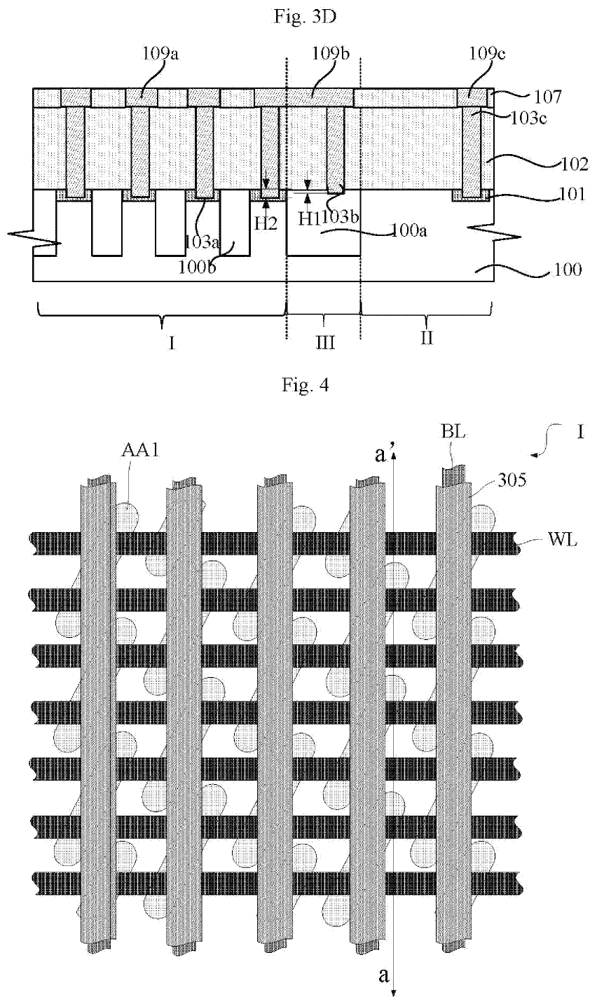

FIG. 3A to FIG. 3D show a device cross-sectional schematic diagram in another manufacturing method for the electrical contact structure of the semiconductor device as shown in FIG. 1C. Please refer to FIG. 3A to FIG. 3D, another manufacturing method for the electrical contact structure of the semiconductor device provided by the present embodiment includes the following operations:

Firstly, please refer to FIG. 3A, a semiconductor substrate 100 is provided, and it includes a core area I, a peripheral area II and a boundary area III located between the core area I and the peripheral area II. Multiple shallow-groove isolation structures 100a and 100b are formed in the semiconductor substrate 100, the shallow-groove isolation structure 100a defines the boundary of the core area I and the peripheral area II on a two-dimensional plane, and the multiple shallow-groove isolation structures 100a define the AA 101 corresponding to each core element in the core area I.

Secondly, please continue to refer to FIG. 3A, the semiconductor substrate 100 is covered by a first interlayer dielectric layer 102. In addition, an etching stop layer (unshown) is formed between the semiconductor substrate 100 and the first interlayer dielectric layer 102; through a first photolithography process, a first mask pattern 104 is formed on the first interlayer dielectric layer 102, the first mask pattern 104 defines a position of each contact plug, and then, the first mask pattern 104 is used as an etching mask, the first interlayer dielectric layer 102 is anisotropically etched, as to form contact holes 102a, 102b and 102c which pass through the first interlayer dielectric layer 102 and expose the corresponding AA 101 below, each contact hole 102a is located in the core area I and exposes the AA 101 of the corresponding core element in the core area I, the contact hole 102b is located in the boundary area III and exposes the isolation structure 100a in the boundary area III, and each contact hole 102c is located in the peripheral area II and exposes the AA 101 of the corresponding peripheral element.

After that, please refer to FIG. 3B, after the contact holes 102a-102c are formed, an ashing process or a wet-type cleaning process can be performed to remove the first mask pattern 104, and each of the contact holes 102a to 102c is filled with a blocking metal layer (unshown) made of a material such as TiN and a metal layer (unshown) made of a material such as tungsten, and chemical-mechanical polishing is further performed on a top surface of the deposited metal layer by using a CMP process, until the top surface of the first interlayer dielectric layer 102 is exposed, as to form the contact plugs 103a, 103b and 103c located in the interlayer dielectric layer 102, a bottom portion of each contact plug 103a in the core area I is in contact with the AA 101 of the corresponding core element, a bottom portion of the contact plug 103b is in contact with the isolation structure 100a in the boundary area III, a bottom portion of each contact plug 103c in the peripheral area II is in contact with the AA 101 of the corresponding peripheral element, and the bottom portion of the first contact plug 103b of the boundary area Ill is stretched into the interior of the isolation structure 100a of the boundary area Ill and a stretching depth is H1, the bottom portion of the contact plug 103a is stretched into the interior of the corresponding AA 101 in the core area I and a stretching depth is H2, the bottom portion of the contact plug 103c is stretched into the interior of the corresponding AA 101 in the peripheral area II and a stretching depth is H2, the H1 is less than the H2.

Then, please refer to FIG. 3C, a second interlayer dielectric layer 107 and a second mask pattern 108 can be formed on the first interlayer dielectric layer 102 and the contact plugs 103a, 103b and 103c, the second mask pattern 108 is formed by a second photolithography process, as to define an interconnected groove (unshown) which is used for connecting top portions of the first contact plug 103b of the boundary area Ill and at least one contact plug 103a in the nearest neighboring core area I and an independent groove which is located in other contact plugs 103a and 103c. The second mask pattern 108 is served as a mask, and the second interlayer dielectric layer 107 is etched, as to form grooves 107a, 107b and 107c for exposing the top portions of the corresponding contact plugs, the corresponding groove 107a in the boundary area III exposes the top portion of the first contact plug 103b and the top portion of at least one contact plug 103a closest to it and a top portion of a gap between two contact plugs, the groove 107b of the core area I exposes the top portion of the corresponding contact plug 103a, and the groove 107c in the peripheral area II exposes the top portion of the corresponding contact plug 103c.

Please refer to FIG. 3D, the second mask pattern 108 can be removed by using oxygen, ozone or ultraviolet ashing process or wet-type cleaning process, and a blocking metal layer (unshown) and a metal layer (unshown) are successively formed in the grooves 107a-107c. The blocking metal layer may reduce or prevent a metal material installed in the contact holes and the grooves from being diffused into the interlayer dielectric layer 102. After that, each of the contact holes and the grooves 107a-107c is filled with the metal layer, as to form mutually independent contact pads 109a, 109b and 109c. Each contact pad 109a is formed on the top portion of the corresponding contact plug 103a of the core area I, and is electrically in contact with the top portion of the corresponding contact plug 103a in one-to-one correspondence, the contact pad 109b is formed on the top portion of the contact plug 103b of the boundary area III, and extended to at least one contact plug 103a in the core area I closest to the contact plug 103b of the boundary area III, and is electrically in contact with the top portion of the corresponding contact plug 103a in one-to-one correspondence, so that all of the contact plugs in the boundary area III of which the top portions are connected together form an inverted U-shaped electrical contact structure or a comb-shaped electrical contact structure.

The method as shown in FIG. 3A to FIG. 3D is capable of, under the same number of photolithography times, manufacturing each contact plug (including the contact plugs of which the top portions are connected together and the independent contact plug) by two height, thereby reducing a depth-width ratio of the contact holes or the grooves corresponding to etching process and filling process in each height, and guaranteeing the performance of the formed electrical contact structure.

It is to be noted that the technical scheme of the disclosure is not just limited to the above forming method for the electrical contact structure, and methods that can be used for forming the independent contact plug and the contact plugs of which the top portions are connected together can be applied to the technical scheme of the disclosure, for example, in another example of the disclosure, after the structure of FIG. 2A is formed and the mask pattern 104 is removed, the sacrificial layer is no longer filled, but the material (including the blocking metal layer and the metal layer) of the contact plug is directly filled, as to form the independent contact plug, and then the second mask pattern 106 in FIG. 2B is formed on the interlayer dielectric layer 102 and the independent contact plug, and the interlayer dielectric layer 102 is further etched, as to form the groove 102d for exposing the top side wall of the first contact plug 103b in the boundary area III and the top side wall of at least one contact plug 103a in the core area I closest to it, after that the groove 102d is filled with a conducting material, as to form the corresponding contact pad (unshown), the contact pad is used for connecting the top portions of the contact plugs 103b and 103a exposed by the groove 102d.

Hereinafter, a semiconductor device and a manufacturing method of the semiconductor device in an embodiment of the disclosure are described in detail with reference to FIG. 4 to FIG. 13. FIG. 4 is a device structure top view schematic diagram in the manufacturing method for the semiconductor device in an embodiment of the disclosure; and FIG. 5 to FIG. 13 are device structure cross-sectional schematic diagrams along a line aa′ in FIG. 4 in the manufacturing method for the semiconductor device in an embodiment of the disclosure.

Firstly, please refer to FIG. 4 and FIG. 5, a substrate 300 having multiple core elements (namely memory transistors) is provided, and a specific process includes the following operations:

Firstly, please refer to FIG. 4 and FIG. 5, a semiconductor base 300a is provided, and it includes a core area I, a peripheral area II and a boundary area III located between the core area I and the peripheral area II. In the present embodiment, the core area I is a memory area, the core element to be formed in the core area I includes a selection element, and a data storage element is subsequently connected above the core element, the selection element is, for example, a MOS transistor or a diode, the data storage element is, for example, a capacitor and a variable resistor, one selection element and the corresponding data storage element form a memory cell. A peripheral circuit (for example, a NMOS transistor and a PMOS transistor, a diode or a resistor) can be formed in the peripheral area II to control the memory cell. Multiple shallow-groove isolation structures 301a and 301b are formed in the semiconductor substrate 300, the shallow-groove isolation structure 301b defines the boundary of the core area I and the peripheral area II on a two-dimensional plane, and the shallow-groove isolation structure 301a also defines the AA1 corresponding to each core element in the core area I and the AA2 corresponding to the peripheral element in the peripheral area II. The distribution of the AA1s on the two-dimensional plane is strip-shaped and extended along a first direction, and the AA1s are alternately arranged and installed on a surface of the semiconductor base 300a.

After that, a WL is formed in the semiconductor base 300a, the WL is generally buried in a predetermined depth in the semiconductor base 300a, extended along a second direction (namely a row direction) and passes through the shallow-groove isolation structure 301a and the AA1, the second direction is intersected with the first direction of the AA1 but is not perpendicular. The WL is served as a gate electrode to control switching of the memory cell, it includes but is not limited to a doped semiconductor material (such as doped silicon), a metal material (such as tungsten, aluminum, titanium, or tantalum), a conductive metal compound (such as a titanium nitride, a tantalum nitride, or a tungsten nitride), or a semiconductor compound (such as a silicon nitride) and the like. Side wall and bottom portion of the buried-type word line are generally surrounded by a gate dielectric layer (unshown), and a top portion of the WL is internally buried by a gate electrode covering layer 302. Because the WL is not a focus point of the disclosure, a related manufacturing process thereof may refer to a known technical scheme in the present field, and is not described in detail here. In addition, the gate dielectric layer may include a silicon oxide or other suitable dielectric materials, the WL may include aluminum, tungsten, copper, titanium aluminum alloy, polysilicon or other suitable conductive materials, and the gate electrode covering layer 302 may include a silicon nitride, a silicon oxynitride, a silicon carbide nitride or other suitable insulation materials.

Furthermore, a second type of a dopant can be doped in the AA1s at both sides of the WL, such as a P-type or N-type dopant, as to form a source area and a drain area (uniformly defined as S/D1), one of the AA1 at the both sides of the buried-type word line WL is located in a center of the AA1 corresponding to a predetermined position of a BL contact structure, and the other is located at a terminal end of the AA1 corresponding to a predetermined position of a storage node contact structure. The WLs and S/D1 may constitute or define multiple MOS memory transistors formed in the core area I of the semiconductor device. In addition, while the S/D1 is formed, a source area and a drain area (uniformly defined as S/D2) corresponding to the peripheral transistor may also be formed in the peripheral area II at the same time. After the S/D1 and S/D2 are formed, an etching stop layer 303 can be further formed on the semiconductor base 300a. The S/D1 and S/D2 are covered by the etching stop layer 303, and a material thereof includes, for example, a silicon nitride (SiN) and/or a silicon oxide (SiO₂).

After that, multiple BL contact plugs (unshown) and BLs located above the BL contact plugs are formed on the S/D1 of the core area I served as the drain area, the BL contact plug can be formed by the following method: firstly, the S/D1 in one AA1 and between two neighboring WLs is etched to form a groove, after that, a metal silicide is formed in the groove. The multiple BLs are parallel to each other and extended along a third direction (namely a column direction) perpendicular to the WL, and cross the AA1 and the WL at the same time. Each BL includes, for example, a semiconductor layer (such as polysilicon, unshown), a barrier layer (such as Ti or TiN, unshown), a metal layer (such as tungsten, aluminum or copper, unshown) and a mask layer (such as a silicon oxide, a silicon nitride or a silicon carbonitride, unshown) which are stacked in turn.

In addition, in the peripheral area II of the semiconductor base 300a, at least one gate electrode structure G1 is formed, and it includes, for example, a gate electrode dielectric layer (unshown) and a gate electrode layer (unshown) which are stacked in turn. In a specific example, the gate electrode layer of the gate electrode structure G1 and the semiconductor layer or the metal layer of the BL are formed together. Further, the different process or the same process can be used to form side walls 304 surrounding each BL and the gate electrode structure G1 respectively. For example, a manufacturing process for the side wall of the gate electrode structure G1 can be firstly performed, so that the side wall 304 of the gate electrode structure G1 includes a silicon oxide or a silicon oxynitride (SiON), and a manufacturing process for the side wall of the BL is performed, so that the side wall of the BL may include a silicon nitride. In addition, in the manufacturing process for the side wall of the gate electrode structure G1, an etching back manufacturing process can be further performed, so that an overall height of the gate electrode structure G1 is lower than that of each BL.

After that, the storage node contact structure can be formed on the basis of using the electrical contact structure of the semiconductor device as shown in FIG. 1A to FIG. 1C of the disclosure, the following is an example of forming the storage node contact structure on the basis of using the manufacturing method for electrical contact structure of the semiconductor device as shown in FIGS. 2A-2D, and a specific process is as follows.

Firstly, please refer to FIG. 6, after the semiconductor substrate 300 having the BL, the source area and drain area S/D1 of the core element is provided, an interlayer dielectric layer 400 is formed on the semiconductor substrate 300, and a material thereof includes, for example, a silicon oxide, a silicon nitride or a low-K medium. Specifically, firstly the semiconductor substrate 300 is completely covered by the interlayer dielectric layer 400 through a deposition process, and spaces between the BLs is filled with the interlayer dielectric layer 400 and each BL and the gate electrode structure G1 and the side walls 304 thereof are buried internally, and then the interlayer dielectric layer 400 is planarized by processes such as CMP, as to form the interlayer dielectric layer 400 which has a planar top surface integrally. The top surface of the planarized interlayer dielectric layer 400 is not lower than a top surface of each BL at least.

Secondly, please refer to FIG. 6, through the photolithography process, a first mask pattern (unshown) is formed on the interlayer dielectric layer 400, the first mask pattern defines a position of each storage node contact structure, and then, the first mask pattern is used as an etching mask, the interlayer dielectric layer 400 is anisotropically etched, as to form contact holes 401a and 401e which pass through the interlayer dielectric layer 400 and expose the corresponding S/D1 below served as the source area, and form 401b for exposing the shallow-groove isolation structure 301a below and 401d for exposing the gate electrode structure G1 below, each contact hole 401a is located in the core area I and exposes the top surface of the S/D1, served as the source area, of the corresponding core element in the core area I and is stretched to a certain depth (as H2 shown in FIG. 1B) in the corresponding S/D1 served as the source area, the contact hole 401b is located in the boundary area Ill and exposes a top surface of the isolation structure 301a in the boundary area Ill and is stretched to a certain depth (as H2 shown in FIG. 1B, the H1 is less than the H2) in the isolation structure 301a, each of the contact holes 401d and 401e is located in the boundary area Ill and exposes the source area/drain area S/D2 of the corresponding peripheral element or the gate electrode structure G1.

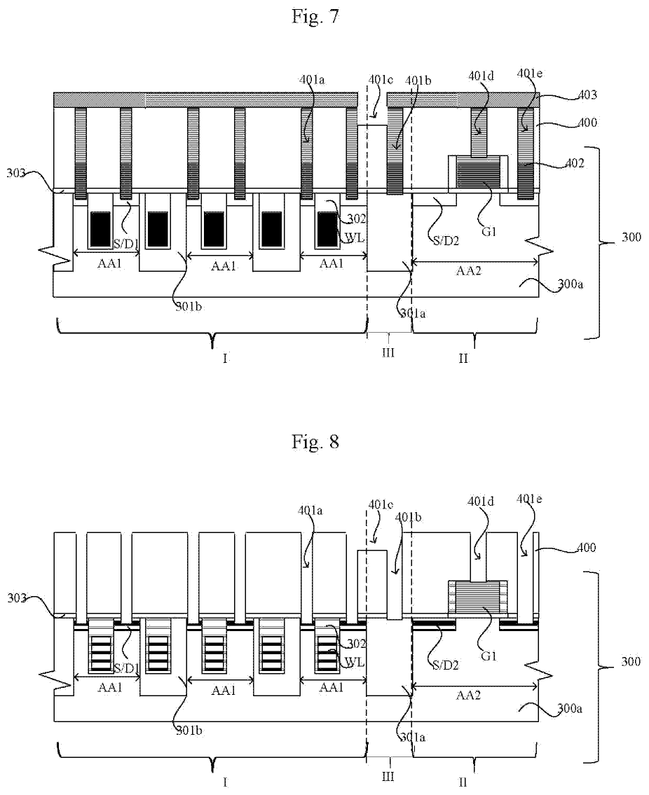

After that, please refer to FIG. 7, after the contact holes 401a, 401b, 401d and 401e are formed, the ashing process or the wet-type cleaning process can be performed, as to remove the first mask pattern, and each of the contact holes 401a, 401b, 401d and 401e is filled with a sacrificial layer 402. The sacrificial layer 402 can be formed by as an SOH or an ACL, so that the contact holes 401a, 401 b, 401d and 401e with a high depth-width ratio can be filled with the sacrificial layer 402.

Subsequently, please continue to refer to FIG. 7, a second mask pattern (unshown) can be formed on the interlayer dielectric layer 400 and the sacrificial layer 402, the second mask pattern defines a groove 401c which is used for connecting the top portion of the corresponding contact hole 401b in the boundary area Ill and the top portion of at least one contact hole 401a in the nearest neighboring core area I thereof. The second mask pattern is served as a mask, the interlayer dielectric layer 400 in the boundary area II is etched, as to form the groove 401c which is used for connecting the top portion of the corresponding first contact hole 401b in the boundary area Ill and the top portion of at least one contact hole 401a in the nearest neighboring core area I thereof. The groove 401c can be parallel to the BL.

After that, please refer to FIG. 7 and FIG. 8, the oxygen, ozone or ultraviolet ashing process or the wet-type cleaning process can be used to remove the sacrificial layer 402 and the second mask pattern in the contact holes 401a, 401b, 401d and 401e, so that each of the contact holes 401a, 401b, 401d and 401e and the groove 401c is exposed again.

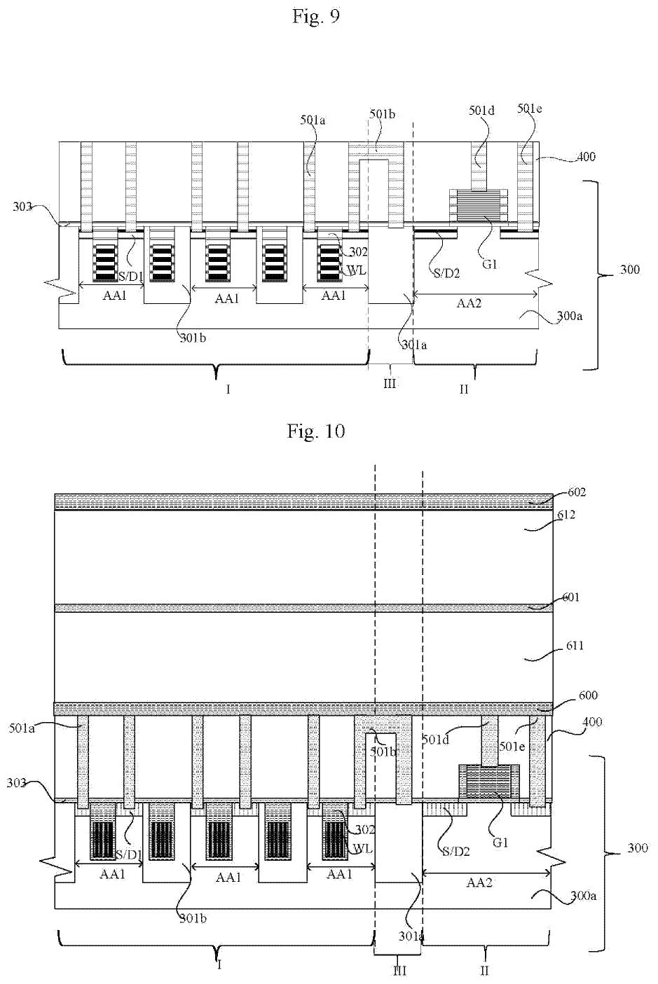

Subsequently, please refer to FIG. 9, a blocking metal layer (unshown) can be formed in the contact holes 401a, 401b, 401d and 401e and the groove 401c, for example, inner walls of the contact holes 401a, 401b, 401d and 401e and the groove 401c and the top surface of the interlayer dielectric layer 400 can be covered by the blocking metal layer in a uniform thickness. The blocking metal layer may reduce or prevent a metal material installed in the contact holes 401a, 401b, 401d and 401e and the groove 401c from being diffused into the interlayer dielectric layer 400. For example, the blocking metal layer can be formed by Ta, TaN, TaSiN, Ti, TiN, TiSiN, W, WN or any combinations thereof, and can be formed by using processes such as CVD, ALD or PVD (for example, sputtering). After that, each of the contact holes 401a, 401b, 401d and 401e and the groove 401c is filled with a metal layer, as to form contact plugs 501a, 501d and 501e and a combined contact structure 501b. The metal layer can be formed by (one or more) refractory metal (for example, cobalt, iron, nickel, tungsten and/or molybdenum). In addition, the metal layer can be formed by using a deposition process with a good stepped covering property, for example, the metal layer can be formed by using the CVD, the ALD or the PVD (for example, sputtering). The metal layer formed by the deposition also covers a surface of the interlayer dielectric layer 400 around the contact holes and the groove, after that, chemical-mechanical polishing can be performed on a top surface of the deposited metal layer by using a CMP process, until the top surface of the interlayer dielectric layer 400 is exposed, as to form the contact plugs 501a, 501d and 501e and the combined contact structure 501b located in the interlayer dielectric layer 400. The contact plug 501a is served as the storage node contact structure in the core area I, and used to connect with a capacitor subsequently formed above the core area I. The combined contact structure 501b is formed by connecting the top portions of the first contact plug in the boundary area III and at least one contact plug 501a (namely at least one contact plug 501a in the core area I closest to the boundary area III) closest to it, served as the storage node contact structure in the core area I and the boundary area III, and used to connect with a capacitor subsequently formed above the core area I and the boundary area III, the combined contact structure 501b can be aligned and parallel to the BL. The combined contact structure 501b is, for example, an inverted U-shaped electrical contact structure or a comb-shaped electrical contact structure, one side thereof closest to the core area I may also be in contact with one word line WL in one AA1 at the outermost side of the core area I. the contact plug 501d is served as the contact structure of the gate electrode structure G1 of the boundary area III, and used to outwards draw out the gate electrode structure G1, the contact plug 501e is served as the contact structure of the source area or drain area S/D2 of the peripheral area II, and used to outwards draw out the source area or drain area S/D2 of the peripheral area II.

After that, a manufacturing method for a conventional capacitor in the present field can be used for manufacturing the corresponding capacitor in the core area I and the boundary area III, please refer to FIGS. 10-13, a specific process is as follows:

Firstly, please refer to FIG. 10, the processes, such as the chemical vapor deposition and the spin-coating, can be used to successively form a bottom support layer 600, a first sacrificial layer 611, an intermediate support layer 601, a second sacrificial layer 612 and a top support layer 602 on the surfaces of the interlayer dielectric layer 400 and the contact plugs 501a, 501d and 501e and the combined contact structure 501b, the bottom support layer 600 is used for performing bottom support on the bottom electrode layer formed subsequently on the one hand, and also used for isolating an element such as an internal element of the semiconductor substrate 300 and the capacitor above on the other hand. A forming process of the bottom support layer 600 may also be a thermal oxidation process. Materials of the bottom support layer 600, the intermediate support layer 601 and the top support layer 602 include but not limited to the silicon nitride, materials of the first sacrificial layer 611 and the second sacrificial layer 612 include but not limited to the silicon oxide. A thickness of the first sacrificial layer 611 defines a height of the intermediate support layer 601 formed subsequently, therefore, the thickness of the first sacrificial layer 611 can be adjusted according to a height position of the intermediate support layer 601 required to be formed. In the case that the thicknesses of the first sacrificial layer 611 and the intermediate support layer 601 are determined, a thickness of the second sacrificial layer 612 defines a height of the top support layer 602 formed subsequently, therefore, the thickness of the second sacrificial layer 612 can be adjusted according to a height position of the top support layer 602 required to be formed. In other embodiments of the disclosure, in order to support the bottom electrode layer better, more than two layers of the intermediate support layers 601 may also be stacked between the bottom support layer 600 and the top support layer 602, and the neighboring intermediate support layers are isolated by the sacrificial layer.

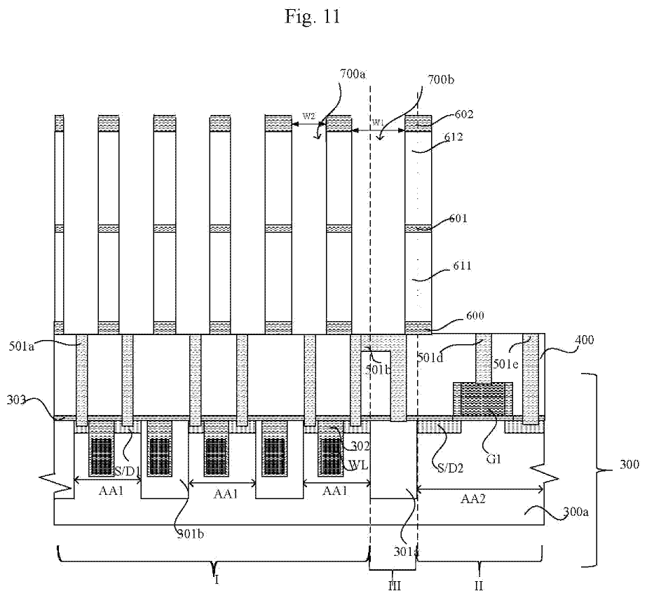

Subsequently, please refer to FIG. 11, multiple capacitance holes 700a and 700b are formed in the sacrificial layer and the support layer on the core area I, each capacitance hole 700a is formed in the core area I and exposes a surface of the corresponding contact plug 501a in the core area I, and is used for forming the capacitor in the core area I. The capacitance hole 700b is formed at the boundary of the core area I and the boundary area III and exposes a surface of the combined contact structure 501b crossing from the boundary area III to the boundary of the core area I, and is used for forming the capacitor across the boundary of the core area I and the boundary area III. The capacitance holes 700a and 700b are arranged in an array, and the capacitance hole 700b has a first width W1, the capacitance hole 700a has a second width W2, optionally W1>W2, for example, the W1 is 1.3*W2˜2.3*W2. Specifically, a mask layer (unshown) is formed on the top support layer 602, the mask layer is patterned to expose a predetermined area for forming the capacitance holes 700a and 700b, and then the patterned mask layer is served as a mask for successively etching the top support layer 602, the second sacrificial layer 612, the intermediate support layer 601, the first sacrificial layer 611 and the bottom support layer 600, as to remove the support layer and the sacrificial layer on fringe areas of the peripheral area II and the core area I, and form multiple capacitance holes 700a and 700b in the core area I and the boundary area III, after that, the patterned mask layer is removed. The capacitance holes 700a and 700b successively pass through the top support layer 602, the second sacrificial layer 612, the intermediate support layer 601, the first sacrificial layer 611 and the bottom support layer 600, as to expose the surfaces of the corresponding contact plug 501a in the core area I and the combined contact structure 501b in the boundary area III, optionally, all of the capacitance holes are arranged in hexagonal close packing. In addition, the capacitance hole can be an inverted trapezoidal hole, a rectangular hole and the like, and a side wall thereof can be an irregular shape, for example, a side wall with a curve, it is not specifically restricted here. In addition, in the present embodiment, the bottom support layer 600 is also reserved on the peripheral area II, and used for protecting a device surface of the peripheral area II in a subsequent capacitor forming process.

It can be understood that because an area of the combined contact structure 501b is larger, a sufficient process margin can be provided for manufacturing the capacitance hole 700b located at the boundary of the core area I and the boundary area III, so that the width of the capacitance hole 700b is larger, and the capacitance hole 700b is avoided from generating abnormal deformation or collapse, at the same time, a contact area between the capacitor subsequently formed in the capacitance hole 700b and the combined contact structure 501b is larger, thereby the contact impedance is reduced, and it is beneficial to improve the electrical performance of the device. In addition, because the width of the capacitance hole 700b of the boundary area III is larger, a density difference between the circuit patterns in the peripheral area II and the core area I can be reduced, thereby while the photolithography process and/or the etching process of the capacitance hole is performed, the optical proximity effect can be improved, the sparse/dense load effect is reduced, the consistency of each capacitance hole in the core area is guaranteed, and a problem that the capacitance hole above the contact plugs in some positions in the core area is abnormal so that the capacitor formed subsequently is failure is prevented.

Please refer to FIG. 12, a bottom electrode layer 701 is formed for covering side walls and bottom walls of the capacitance holes 700a and 700b. The bottom electrode layer 701 is located in a part of the capacitance holes 700a and 700b, and a shape thereof is consistent with shapes of the capacitance holes 700a and 700b, thereby the bottom electrode layer 701 located in the capacitance holes 700a and 700b forms a cylinder-shaped structure. Specifically, the bottom electrode layer 701 can be formed on the basis of the deposition process in combination with a planarization process, for example, firstly, a patterned protecting layer (unshown) such as a photoresist can be used for protecting the peripheral area II, and exposing a top surface of the top support layer 602 in the core area I and surfaces of the capacitance holes 700a and 700b; secondly, processes such as the physical vapor deposition or chemical vapor deposition are used for forming an electrode material layer on the patterned protecting layer and the exposed surface of the core area I, the electrode material layer covers the bottom portions and the side walls of the capacitance holes 700a and 700b, and covers the top surfaces of the top support layer 602 of the core area I and the patterned protecting layer of the peripheral area II; and then, the planarization process (for example, a chemical mechanical polishing process CMP) is performed to remove a part, located above the top support layer 602, in the electrode material layer, thereby the remaining electrode material layer is only formed in the capacitance holes 700a and 700b, as to form the bottom electrode layer 701 with multiple cylinder-shaped structures, after that, the patterned protecting layer is removed. In addition, in the present embodiment, the contact plugs 501a and 501b are respectively exposed by the capacitance holes 700a and 700b, so that a bottom portion of the cylinder-shaped structure of the formed bottom electrode layer 701 is electrically in contact with the contact plugs 501a and 501b. Further, the bottom electrode layer 701 can be a polysilicon electrode or a metal electrode. While the bottom electrode layer 701 is the metal electrode, a titanium nitride (TiN) and Ti stacked structure may also be used. While the bottom electrode layer 701 is the polysilicon electrode, it can be formed by using a zero-doped and/or doped polysilicon material.

Please continue to refer to FIG. 12, each of the sacrificial layers is removed and each of the support layers is reversed, all of the support layers form a lateral support layer, as to crosswise connect outer walls of the multiple cylinder-shaped structures of the bottom electrode layer 701, so that the bottom electrode layer 701 is supported on the side wall of each of the cylinder-shaped structures. Specifically, the top support layer 602 is located at a top periphery of the multiple cylinder-shaped structures of the bottom electrode layer 701, the intermediate support layer 601 is located at an intermediate portion of the multiple cylinder-shaped structures of the bottom electrode layer 701, and the bottom support layer 600 is located at a bottom periphery of the multiple cylinder-shaped structures of the bottom electrode layer 701. A specific process includes the following operations: a first opening (unshown) is formed in the top support layer 602 and exposes the second sacrificial layer 612; a wet etching process can be used for etching and removing the second sacrificial layer 612; a second opening is formed in the intermediate support layer 601 so as to expose the first sacrificial layer 611; the wet etching process is used for etching and removing the first sacrificial layer 611; one first opening is only overlapped with one capacitance hole 700a or 700b, or one first opening is overlapped with multiple capacitance holes 700a and/or 700b at the same time; one second opening is only overlapped with one capacitance hole 700a and/or 700b, or one second opening is overlapped with multiple capacitance holes 700a and/or 700b at the same time. In addition, the second opening can be completely aligned with the first opening.

Please refer to FIG. 13, the chemical vapor deposition process or the atomic layer deposition process and the like are used for forming a capacitance dielectric layer 702 on inner and outer surfaces of the bottom electrode layer 701 and the exposed surface of each of the support layers; subsequently, a top electrode layer 703 is formed on an inner surface and an outer surface of the capacitance dielectric layer 702. The capacitance dielectric layer 702 covers the inner surface and the outer surface of the cylinder-shaped structure of the bottom electrode layer 701, as to adequately use two opposite surfaces of the bottom electrode layer 701, and form a capacitor with a larger electrode surface area. Preferably, the capacitance dielectric layer 702 can be a high-K dielectric layer such as a metal oxide. Further, the capacitance dielectric layer 702 is a multi-layer structure, for example, a two-layer structure of hafnium oxide-zirconium oxide. The top electrode layer 703 can be a single-layer structure or may also be the multi-layer structure, while the top electrode layer 703 is the single-layer structure, for example, it is the polysilicon electrode, and it may also be the metal electrode, while the top electrode layer 703 is the metal electrode, for example, it can be formed by using the titanium nitride (TiN). The top electrode layer 703 may form the capacitor with the capacitance dielectric layer 702 and the bottom electrode layer 701 both inside the corresponding cylinder-shaped structure and outside the cylinder-shaped structure. In addition, in the fringe area (namely a boundary area of a capacitance hole array) of the core area I, because of the presence of the lateral support layer (namely the intermediate support layer 601 and the top support layer 602), the capacitance dielectric layer 702 and the top electrode layer 703 both have side wall structures with concave-convex uneven shapes, the side wall structures with the concave-convex uneven shapes correspond to the intermediate support layer 601 and the top support layer 602 outside the cylinder-shaped structures of the bottom electrode layer 701, so that a portion, located in the fringe area (namely the boundary area of the capacitance hole array) of the core area I, of the top electrode layer 703 corresponds to the intermediate support layer 601 and the top support layer 602 and is protruded in a direction away from the bottom electrode layer 701, and the boundary of the capacitance hole array in the core area I is uneven. In addition, in the present embodiment, the capacitance dielectric layer 702 and the top electrode layer 703 are also successively extended for covering the surface of the bottom support layer 600 reserved in the peripheral area II.

Please refer to FIG. 13, the chemical vapor deposition process can be firstly used for forming a top electrode filling layer 704 on the surface of the top electrode layer 703, and a gap between the top electrode layers 703 is filled with the top electrode filling layer 704, in other words, a gap between the neighboring cylinder-shaped structures is filled with the top electrode filling layer 704 and the above formed structure is covered. Preferably, a material of the top electrode filling layer 704 includes undoped or boron-doped polysilicon. Thus manufacturing of the capacitor array is completed, namely multiple capacitors 705a are formed in the core area I, and the capacitor 705b is formed at the boundary of the core area I and the boundary area III.

Because a width of the capacitance hole 700b is greater than a width of the capacitance hole 700a, a width (namely the W1) of the capacitor 705b is greater than a width (namely the W2) of each capacitor 705a in the core area I, for example, W1=1.3*W2˜2.3*W2, as an example, W1=W2*1.5. In addition, because the size of the capacitance hole 700b is larger, it is beneficial to material filling, thereby the performance of the capacitor 705b is improved.

In the manufacturing method for the semiconductor device of the present embodiment, through the combined contact structure 501b, the size of the capacitor 705b connected to it is increased, and the density difference of the circuit patterns between the core area and the peripheral area can be reduced, thereby in the photolithography process and/or the etching process of forming all of the capacitors in the core area, the optical proximity effect can be improved, the sparse/dense load effect is reduced, the consistency of the capacitors above the contact plugs in the core area is guaranteed, and the device performance is improved. In addition, there is a larger contact area between the capacitor 705b and the combined contact structure 501b, thereby the contact impedance is reduced, and it is beneficial to improve the electrical property of the device.

In the manufacturing method for the semiconductor device in other embodiments of the disclosure, while the first contact plug 501b formed in the boundary area III is completely overlapped with the isolation structure 300a of the boundary area III, please refer to FIG. 1A and FIG. 13, the capacitor 705b originally crosswise extended from the boundary area III to the outermost side of the core area I can be completely formed above the isolation structure 300a of the boundary area III and served as a virtual structure, thereby the consistency of the electrical structure 705a connected to the contact plug 501a of the core area I is guaranteed by the virtual structure; and while a part of the bottom portion of the first contact plug 501b formed in the boundary area III is overlapped with the isolation structure 300a of the boundary area III, and the other part of the bottom portion is overlapped with the AA 301 of the core area I next to the isolation structure 300a of the boundary area III, please refer to FIG. 1B and FIG. 13, a top cross-sectional area of the first contact plug 501b formed in the boundary area III is relatively increased, the sufficient process margin is also provided for a subsequence process of forming the capacitor 705b above the first contact plug 501b, it is beneficial to increase the size of the capacitor 705b of the boundary area III, and abnormity or collapse of the capacitor 705b is avoided; on the other hand, there is a larger contact area between the capacitor 705b and the first contact plug 501b, thereby the contact impedance is reduced, and it is beneficial to improve the electrical property of the device; and it is more important that through the first contact plug 501b, the size of the capacitor 705b connected to it is increased, and the density difference of the circuit patterns between the core area I and the peripheral area II can be reduced, thereby in the photolithography process and/or the etching process of forming all of the capacitors 705a in the core area I, the optical proximity effect can be improved, the sparse/dense load effect is reduced, the consistency of the capacitors 705b above the contact plug 501a in the core area I is guaranteed, and the device performance is improved.

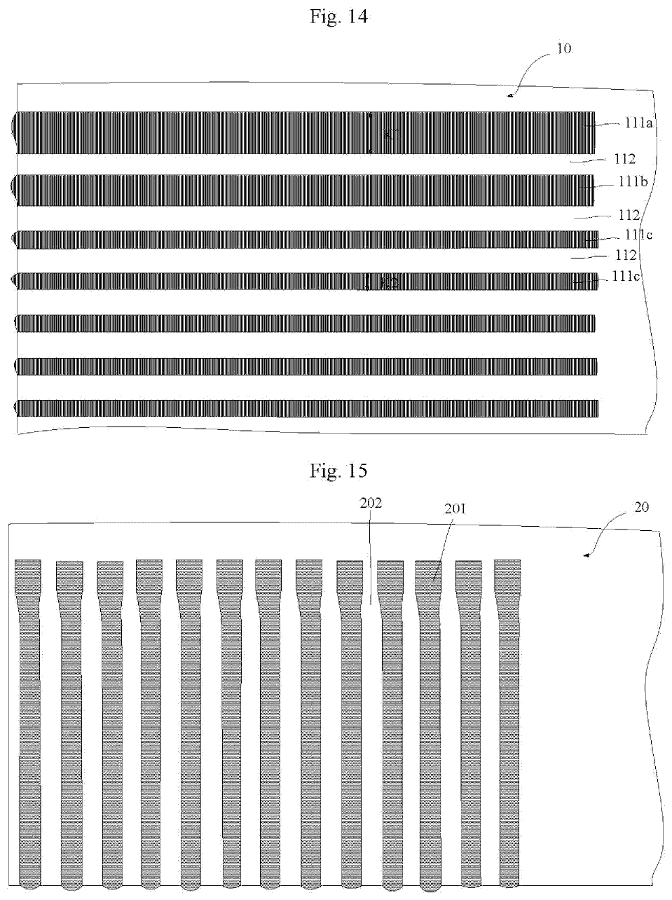

Subsequently, please refer to FIG. 14 to FIG. 16, an embodiment of the disclosure provides a mask plate combination which is used for manufacturing a contact plug, the mask plate combination includes: a first mask plate 10, a second mask plate 20 and a third mask plate 30.

Please refer to FIG. 14, the first mask plate 10 has multiple parallel first light-shielding strips, it is a first light-transmitting area 112 between the neighboring two first light-shielding strips. In the present embodiment, the first one of the first light-shielding strip 111a at a boundary (namely the boundary along an arrangement direction of the first light-shielding strips) of the first mask plate 10 has a first width K1, a width of the second one of the first light-shielding strip 111b is less than the K1, the rest first light-shielding strips 111c have a second width K2, and the first width K1 is greater than the second width K2, for example, K1>1.5*K2, and the width of the second one of the first light-shielding strip 111b is greater than the K2, thereby in photolithography and etching processes of transferring a pattern on the first mask plate 10 to a corresponding film layer, a width gradual change of the first one of the first light-shielding strip 111a, the second one of the first light-shielding strip 111b and the rest first light-shielding strips 111c in the first mask plate 10 can be used to improve a pattern dense/sparse effect between the core area and the peripheral area of the semiconductor device, and improve a pattern transferring effect of the first mask plate 10. In other embodiments of the disclosure, the width of the second one of the first light-shielding strip 111b can be equal to the width of the first one of the first light-shielding strip 111a. In addition, optionally, a width of the first light-transmitting area 112 between the first one of the first light-shielding strip 111a and the second one of the first light-shielding strip 111b is greater than widths of the rest first light-transmitting areas 112, thereby it is beneficial to provide the sufficient process margin for manufacturing the contact plug at the boundary of the core area of the semiconductor device.

Please refer to FIG. 15, the second mask plate 20 has multiple parallel second light-shielding strips 201 perpendicularly intersected with each of the first strips 111a, 111 b and 111c, and it is a second light-transmitting area 202 between the neighboring two second light-shielding strips 201. Widths of the second light-shielding strips 201 shown in FIG. 15 are the same basically, but in other embodiments of the disclosure, optionally, at least one second light-shielding strip (unshown) at a boundary (namely the boundary along an arrangement direction of the second light-shielding strips) of the second mask plate 20 has a third width (unshown), the rest second light-shielding strips have a fourth width (unshown), and the third width is greater than the fourth width, for example, the third width is greater than 1.5 times of the fourth width, thereby in photolithography and etching processes of transferring a pattern on the second mask plate 20 to a corresponding film layer, a width gradual change of the second light-shielding strips in the second mask plate 20 can be used to improve the pattern dense/sparse effect between the core area and the peripheral area of the semiconductor device, and improve the pattern transferring effect of the second mask plate 20. In other embodiments of the disclosure, optionally, the width of the second light-transmitting area 202 between the first one of the second light-shielding strip and the second one of the second light-shielding strip at the boundary (namely the boundary along the arrangement direction of the second light-shielding strips) of the second mask plate 20 is greater than the widths of the rest second light-transmitting areas 202, thereby it is beneficial to provide the sufficient process margin for manufacturing the contact plug at the boundary of the core area of the semiconductor device.

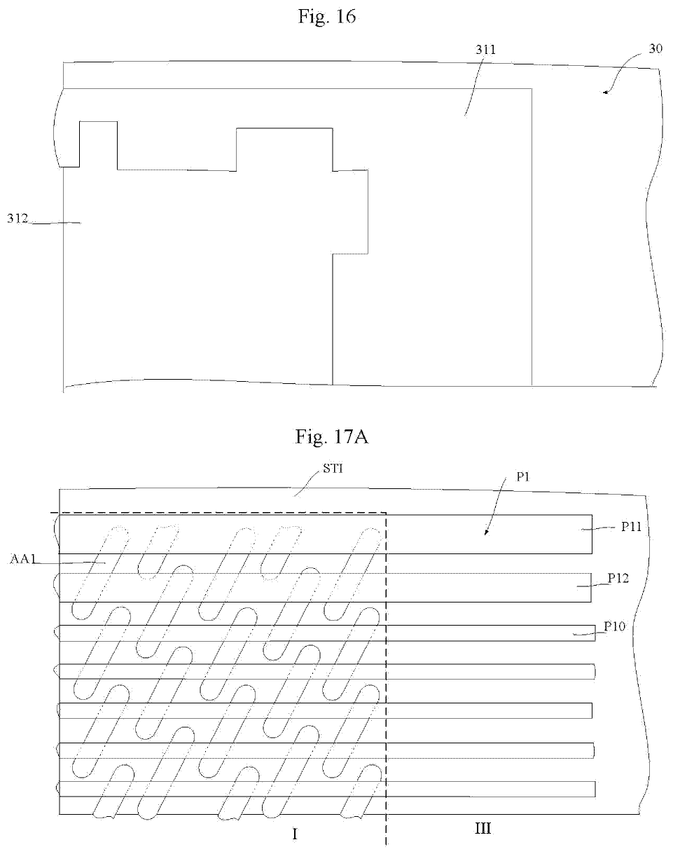

Please refer to FIG. 16, the third mask plate 30 has a light-shielding block 311 and a third light-transmitting area 312 complementary to the light-shielding block 311. The light-shielding block 311 may have a sawtooth-shaped fringe towards the core area, which is used for shielding a part of an area, for forming the contact hole, at the boundary of the core area.

It is to be noted that FIG. 14 to FIG. 16 only show patterns in one corner area of the first mask plate 10, the second mask plate 20 and the third mask plate 30, those skilled in the art should be able to perform corresponding extension according to the area shown in FIG. 14 to FIG. 16 so as to obtain a basically rectangular complete mask plate. In addition, the light-shielding block 311 is a closed ring-shaped structure on the complete third mask plate 30 or a non-closed ring-shaped structure with at least one opening, a sawtooth-shaped fringe, towards a center of the third mask plate 30, of the light-shielding block 311 is non-symmetrical, namely the light-shielding blocks 311 at upper side and lower side of the third mask plate 30 are non-symmetrical, and the light-shielding blocks 311 at left side and right side of the third mask plate 30 are non-symmetrical.

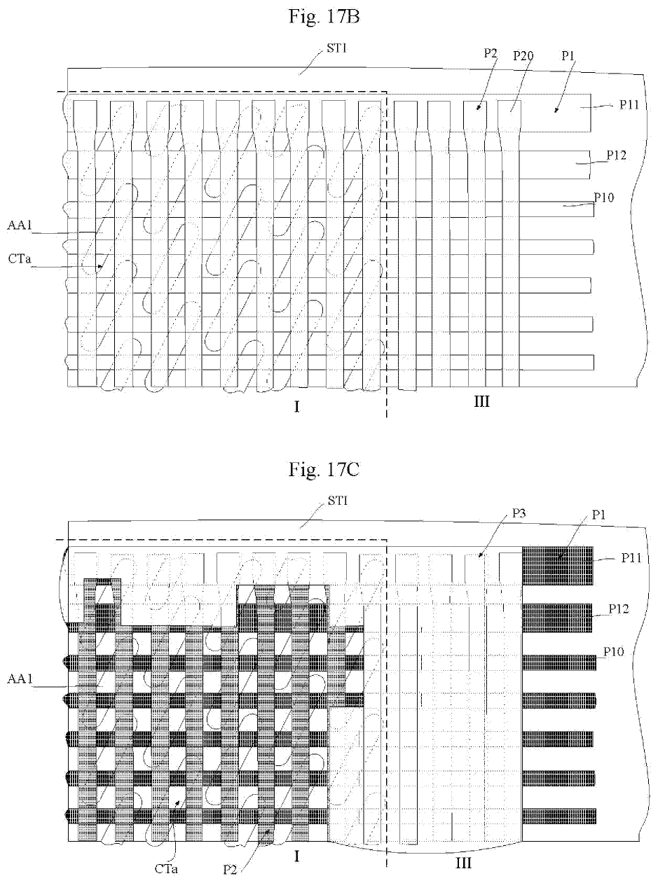

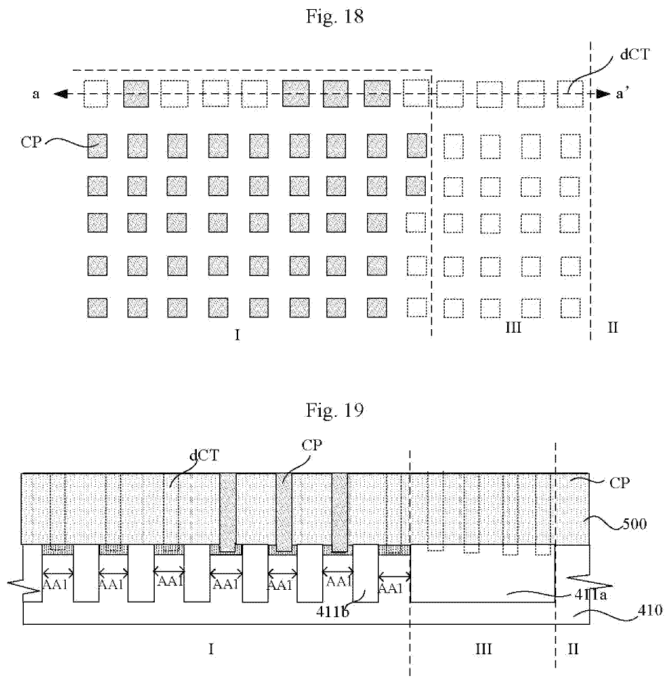

Please refer to FIG. 17C and FIG. 18, while the mask plate combination in the present embodiment is used for manufacturing the contact plug on a semiconductor substrate having a core area I, a boundary area III and a peripheral area II, the light-shielding block 311 covers at least one first light-shielding strip at the boundary of the first mask plate 10 and a part of the first light-transmitting area closest to the first light-shielding strip, and covers at least two second light-shielding strips 201 at the boundary of the second mask plate 20 and a part of the second light-transmitting area 202 between the two second light-shielding strips. In addition, an overlapping area of the third light-transmitting area 312, the first light-transmitting area 112 and the second light-transmitting area 202 with the core area I is an area CP for forming the contact plug. Optionally, according to shapes of the first light-shielding strips and shapes of the second light-shielding strips, a shape of the area CP for forming the contact plug includes at least one of a square, a round, an ellipse, a triangle, a rectangle, a polygon and a heart shape.

In addition, in order to give consideration to problems such as device density, properties and a pass rate as much as possible, the number of the second light-shielding strips 201 covered by the light-shielding block 311 is 2-5 times greater than the number of the first light-shielding strips covered by the light-shielding block 311.

Please refer to FIGS. 14-16, FIGS. 17A-17C and FIGS. 18-19, an embodiment of the disclosure further provides a manufacturing method of a contact plug, the contact plug manufacturing method is achieved by using the mask plate combination of the disclosure, and a specific process includes the following steps.

Firstly, please refer to FIG. 17A and FIG. 19, a semiconductor substrate 410 having multiple AA1s is provided, and an interlayer dielectric layer 500 and a first mask layer P1 are formed on the semiconductor substrate 410 in turn, the semiconductor substrate 410 also has a core area I, a peripheral area II and a boundary area III located between the core area I and the peripheral area II, a shallow-groove isolation structure 411b for defining each of the AA1s is formed in the core area I, a shallow-groove isolation structure 411a for defining the core area I and the peripheral area II is formed in the boundary area III, and a material of the first mask layer P1 can be a silicon oxide, a silicon nitride or a silicon oxynitride and the like.

Subsequently, please refer to FIG. 14, FIG. 17A and FIG. 19, through using the process of photolithography in combination with etching, the pattern on the first mask plate in the mask plate combination is transferred to the first mask layer P1, namely the first mask layer P1 is patterned by using the first mask plate 10. Specifically, firstly the first mask layer P1 is successively covered by a bottom anti-reflecting layer (unshown) and a photoresist layer (unshown), and the photoresist layer is exposed and developed by using the first mask plate 10, so that the pattern on the first mask plate 10 is transferred to the first mask layer P1, after that, the bottom anti-reflecting layer and the photoresist layer can be removed. Multiple first lines are formed in the patterned first mask layer P1, each first line corresponds to the corresponding first light-shielding strip on the first mask plate 10, a groove (unmarked) between the neighboring first lines corresponds to the corresponding first light-transmitting area 112 on the first mask plate 10 and exposes the corresponding interlayer dielectric layer 500. Specifically, for example, the first one of the first line P11 at the outermost side of the boundary (namely the boundary of the core area I along an arrangement direction of the first lines) of the core area I corresponds to the first one of the first light-shielding strip 111a at the boundary of the first mask plate 10, the second one of the first line P12 corresponds to the second one of the first light-shielding strip 111b at the boundary of the first mask plate 10, and the rest first lines P10 correspond to the rest first light-shielding strips 111c inside the first mask plate 10.

After that, please refer to FIG. 15, FIG. 17B and FIG. 19, the first mask layer P1 and the interlayer dielectric layer 500 are covered by a second mask layer P2, and the process of photolithography in combination with etching is used for transferring the pattern on the second mask plate 20 in the mask plate combination to the second mask layer P2, as to form multiple corresponding second lines P20. Namely, the second mask layer P2 is patterned by using the second mask plate 20. A specific process is the same as the process of patterning the first mask layer P1 by using first mask plate, and it is not described in detail here. Each second line P20 corresponds to the corresponding second light-shielding strip 201 on the second mask plate 20, a groove (unmarked) between the neighboring second lines P20 corresponds to the corresponding second light-transmitting area 202 on the second mask plate 20, each second line P20 is perpendicularly intersected with all of the first lines P11, P12 and P10 and these first lines P11, P12 and P10 and a corresponding portion of the groove between the neighboring first lines are covered in a line width area thereof, and the groove between the neighboring second lines P20 exposes the corresponding first lines P11, P12 and P10 in the groove width area and the interlayer dielectric layer 500 in the groove between the neighboring first lines. At this moment, all of the first lines and the second lines are overlapped to define grooves CTa (unmarked) arranged in a chessboard shape. A material of the second mask layer P2 is different from a material of the first mask layer P1, so that the first line between the neighboring second lines can be reserved by the above etching process.

Subsequently, please refer to FIG. 16, FIG. 17C and FIG. 19, the second mask layer P2, the first mask layer P1 and the interlayer dielectric layer 500 are covered by a third mask layer P3, a material of the third mask layer P3 is different from the material of the second mask layer P2 and the material of the first mask layer P1, so that the first line and the second line exposed by the third mask layer can be reserved after the third mask layer P3 is subsequently patterned, optionally, the material of the third mask layer P3 is a photoresist; and a pattern on the third mask plate 30 in the mask plate combination is transferred to the third mask layer P3 by using the etching process, namely the third mask layer P3 is patterned by using the third mask plate 30, the rest third mask layer P3 (namely the patterned third mask layer P3) corresponds to the light-shielding block 311 of the third mask plate 30, the groove CTa area (namely the exposed interlayer dielectric layer 500 area) jointly exposed by the rest third mask layer P3 and the rest second mask layer P2 and first mask layer P1 is an area for forming the contact plug. All of the grooves defined by intersection of the first lines and the second lines in the boundary area III are covered, and a part of the grooves defined by intersection of the first line and the second line at the outermost side of the boundary in each direction of the core area I is covered by the rest third mask layers P3. In addition, it is to be noted that in the present embodiment, the WL can be overlapped with the second line P20, the first lines P10-P12 can be correspondingly overlapped with the BL. Therefore, the first mask plate 10 can be a BL mask plate, and the second mask plate 20 can be a word line mask plate.

Subsequently, please refer to FIG. 17C, FIG. 18 and FIG. 19, the rest third mask layer P3, second mask layer P2 and first mask layer P1 are served as masks, as to etch the exposed interlayer dielectric layer 500, until the AA1 in the semiconductor substrate 410 is exposed, as to expose the contact hole of the corresponding AA1. In the present embodiment, because of a shielding effect of the third mask layer P3, there is the contact hole (as shown in a block CT of a solid line frame in a line aa′ in FIG. 18) in a part of the AA1s at the boundary, along the arrangement direction of the first lines, of the core area I, and there is no contact hole (as shown in a block dCT of a dotted line frame in the line aa′ in FIG. 18) in the other part of the AA1s.

After that, please refer to FIG. 18 and FIG. 19, the contact plug CP is formed in each of the contact holes, and a bottom portion of each of the contact plugs CPs is in contact with the corresponding AA1. It can be observed from FIG. 19 that there is no contact plug above a part of the AA1s at the boundary, along a length extending direction of the first line or the second line, of the core area I, as shown in dCT in FIG. 19. In addition, in some embodiments, the contact plugs CPs at the boundary of two opposite sides of the core area I are asymmetrically distributed, for example, the contact plugs at the upper side boundary and the lower side boundary of the core area I are asymmetrically distributed, and/or, the contact plugs at the left side boundary and the right side boundary of the core area I are asymmetrically distributed. It can be observed from the contact plug manufacturing method of the disclosure that a position of the groove defined by the intersection of the first line and the second line covered by the patterned third mask layer can be adjusted by adjusting a shape and a size of the light-shielding block of the third mask plate, thereby a requirement that there is no contact plug above the AA in some special positions at the boundary of the core area is achieved. Therefore, in an actual manufacturing process, areas in which problems easily happen at the boundary of the core area can be collected according to historical production data, so that the contact plug is not formed in these areas, the electrical structure (for example, a capacitor or a resistor) originally connected in a contact plug position in these areas becomes a virtual structure, and does not participate in a subsequent test such as a yield test, thereby a test pass rate can be improved, and finally a purpose of improving a product pass rate is achieved.

The semiconductor device served as a dynamic random access memory is taken as an example below, and in combination with FIGS. 14-16, FIGS. 17A-17C, FIG. 18 and FIG. 20, how to manufacture the semiconductor device of the disclosure by the above manufacturing method for the contact plug is described in detail, namely the manufacturing method for the semiconductor device of the disclosure, it specifically includes the following processes:

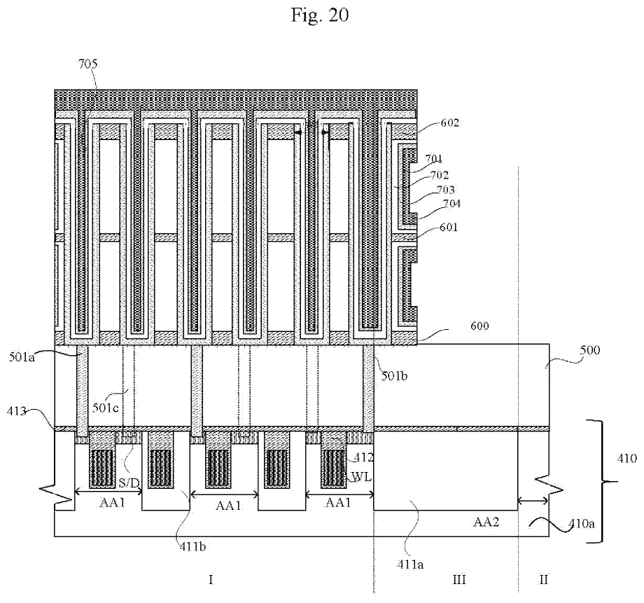

Firstly, please refer to FIG. 17A and FIG. 20, a semiconductor substrate 410 having multiple core elements (namely memory transistors) is provided, and a specific process includes the following operations: firstly, a semiconductor base 410a is provided, and it includes a core area I, a peripheral area II and a boundary area III. In the present embodiment, the core area I is a memory area, a core element to be formed in the core area I includes a selection element, and a data storage element is subsequently connected above the core element, the selection element is, for example, a MOS transistor or a diode, the data storage element is, for example, a capacitor and a variable resistor, one selection element and the corresponding data storage element form a memory cell. A peripheral circuit (for example, a NMOS transistor and a PMOS transistor, a diode or a resistor) can be formed in the peripheral area II to control the memory cell. Multiple shallow-groove isolation structures 411b are formed in the semiconductor base 410a of the core area I, a shallow-groove isolation structure 411a is formed in the semiconductor base 410a of the boundary area III, the shallow-groove isolation structure 411a defines the boundary of the core area I and the peripheral area II on a two-dimensional plane, and the shallow-groove isolation structures 411b define the AA1 corresponding to each core element in the core area I. The distribution of the AA1s on the two-dimensional plane is strip-shaped and extended along a first direction, and the AA1s are alternately arranged and installed on a surface of the semiconductor base 410a. After that, a WL is formed in the semiconductor base 410a, the WL is generally buried in a predetermined depth in the semiconductor base 410a, extended along a second direction (namely a row direction) and passes through the shallow-groove isolation structures 411b and the AA1, the second direction is intersected with the first direction of the AA1 but is not perpendicular. The WL is served as a gate electrode to control switching of the memory cell, a side wall and a bottom portion of the WL are generally surrounded by a gate dielectric layer (unshown), and a top portion of the WL is internally buried by a gate electrode covering layer 412. Because the WL is not a focus point of the disclosure, a related manufacturing process thereof may refer to a known technical scheme in the present field, and is not described in detail here. In addition, the gate dielectric layer may include a silicon oxide or other suitable dielectric materials, the WL may include aluminum, tungsten, copper, titanium aluminum alloy, polysilicon or other suitable conductive materials, and the gate electrode covering layer 412 may include a silicon nitride, a silicon oxynitride, a silicon carbide nitride or other suitable insulation materials. Furthermore, a second type of a dopant can be doped in the AA1 at both sides of the WL, such as a P-type or N-type dopant, as to form a source area and a drain area (uniformly defined as SID), one of the AA1 at the both sides of the WL is located in a center of the AA1 corresponding to a predetermined position of a BL contact structure, and the other is located at a terminal end of the AA1 corresponding to a predetermined position of a storage node contact structure. The WLs and S/D1 may constitute or define multiple MOS memory transistors formed in the core area I of the semiconductor device. In addition, while the SID is formed, a source area and a drain area (unshown) corresponding to the peripheral transistor may also be formed in the peripheral area II at the same time. After the SID is formed, an etching stop layer 413 can be further formed on the semiconductor base 410a. The SID and the shallow-groove isolation structures 411a and 411B are covered by the etching stop layer 413, and a material thereof includes, for example, a silicon nitride (SiN) and/or a silicon oxide (SiO₂). After that, multiple BL contact plugs (unshown) and BLs located above the BL contact plugs are formed on the SID of the core area I served as the drain area, the BL contact plug can be formed by a method that firstly the SID between two neighboring WLs is etched to form a groove, after that, a metal silicide is formed in the groove. The multiple BLs are parallel to each other and extended along a third direction (namely a column direction) perpendicular to the WL, and cross the AA1 and the WL at the same time. Each BL includes, for example, a semiconductor layer (such as polysilicon, unshown), a barrier layer (such as Ti or TiN, unshown), a metal layer (such as tungsten, aluminum or copper, unshown) and a mask layer (such as a silicon oxide, a silicon nitride or a silicon carbonitride, unshown) which are stacked in turn.

After that, please refer to FIG. 17A and FIG. 20, after the semiconductor substrate 410 having the BL, the source area and drain area SID of the core element is provided, an interlayer dielectric layer 500 is formed on the semiconductor substrate 410, and a material thereof includes a silicon oxide, a silicon nitride or a low-K medium and the like. Specifically, firstly the semiconductor substrate 410 is completely covered by the interlayer dielectric layer 500 through a deposition process, and spaces between the BLs is filled with the interlayer dielectric layer 500 and each BL is buried internally, and then the interlayer dielectric layer 500 is planarized by processes such as chemical-mechanical polishing, as to form the interlayer dielectric layer 500 which has a planar top surface integrally. The top surface of the planarized interlayer dielectric layer 500 is at least higher than a top surface of each BL.

Secondly, please refer to FIG. 14 to FIG. 16, FIG. 17A to FIG. 17C, FIG. 18 and FIG. 20, through the above manufacturing method for the contact plug, the first mask layer P1 having the pattern of the first mask plate 10, the second mask layer P2 having the pattern of the second mask plate 20, and the third mask layer P3 having the pattern of the third mask plate 30 are successively formed on the interlayer dielectric layer 500, a specific process may refer to the above and is not described in detail here. The second mask layer P2 is formed on the first mask layer P1 and the interlayer dielectric layer 500 exposed by it, the third mask layer P3 is formed on the second mask layer P2 and the first mask layer P1 and interlayer dielectric layer 500 exposed by it, the first line in the first mask layer P1 and the second line in the second mask layer P2 are perpendicularly intersected and define some grooves arranged in a chessboard shape, the third mask layer P3 is used for shielding all of the grooves in the boundary area III and a part of grooves at the boundary of the core area I, as to define a position of each effective storage node contact structure.

After that, please continue to refer to FIG. 17C, FIG. 18 and FIG. 20, the third mask layer P3, the second mask layer P2 and the first mask layer P1 are served as masks, and the interlayer dielectric layer 500 is anisotropically etched to form a contact hole that passes through the interlayer dielectric layer 500 and exposes the corresponding SID below used as the source area, and simultaneously form a contact hole (unshown) which exposes the corresponding area in the peripheral area II at this moment. The size of the contact hole at the boundary of the core area I can be greater than the size of the contact hole inside the core area I. In other embodiments of the disclosure, the contact hole may also be formed in the area of the boundary area III close to the boundary of the core area I, and the top portion of the contact plug subsequently formed in the contact hole in the boundary area III can be connected with the top portion of the corresponding contact plug at the boundary of the core area I together.

Subsequently, please continue to refer to FIG. 18 and FIG. 20, after the contact holes are formed, the ashing process or the wet-type cleaning process or other suitable processes can be performed to remove the third mask layer P3, the second mask layer P2 and the first mask layer P1 above the interlayer dielectric layer 500, and each contact hole is successively filled with a blocking metal layer (unshown) and a conductive metal layer (unshown), the blocking metal layer may cover inner walls of the contact holes and a top surface of the interlayer dielectric layer 500 in a uniform thickness, and the blocking metal layer may reduce or prevent a metal material installed in the contact hole from being diffused into the interlayer dielectric layer 500. The blocking metal layer can be formed by Ta, TaN, TaSiN, Ti, TiN, TiSiN, W, WN or any combinations thereof, and can be formed by using processes such as a CVD, an ALD) or a PVD (for example, sputtering); and the conductive metal layer can be formed by (one or more) refractory metal (for example, cobalt, iron, nickel, tungsten and/or molybdenum). In addition, the conductive metal layer can be formed by using a deposition process with a good stepped covering property, for example, the conductive metal layer can be formed by using the CVD, the ALD or the PVD (for example, sputtering). The conductive metal layer formed also covers a surface of the interlayer dielectric layer 500 around the contact holes, after that, chemical-mechanical polishing can be performed on a top surface of the deposited conductive metal layer by using a CMP process, until the top surface of the interlayer dielectric layer 500 is exposed, as to form the contact plug CP located in the interlayer dielectric layer 500. FIG. 20 shows that there is no contact plug above a part of the AA1s at the boundary of the core area I (for these positions, the contact plug can be formed in the related art, but not formed in the disclosure, namely a dotted line frame column dCT is used for comparison in FIG. 20), and there is the contact plug CP above the other part of the AA1s. The contact plug CP is served as the storage node contact structure in the core area I, and used to connect with the capacitor subsequently formed above the core area I.

After that, please continue to refer to FIG. 20, a conventional manufacturing method for a capacitor in the related art can be used for manufacturing the corresponding capacitor in the core area I, and a specific process is not described in detail here. One capacitor 705 is formed above each SID of the core area I, at the boundary of the core area I, the capacitor 705 of which a bottom portion is electrically connected with the corresponding SID through the corresponding contact plug CP is an effective capacitor, and is subsequently used for participating in a test and a device operation, and the capacitor without the contact plug CP between the bottom portion and the corresponding SID is a virtual capacitor, and is not subsequently used for participating in the device related test and the device operation, therefore, the pass rate of the product is improved. In the present embodiment, each capacitor 705 includes a bottom electrode layer 701, a capacitance dielectric layer 702 and a top electrode layer 703, a bottom support layer 600, an intermediate support layer 601 and a top support layer 602 which are laterally supported and stacked in an interval-type are between the capacitors 705, the bottom support layer 600 is used for performing bottom support on the bottom electrode layer formed subsequently on the one hand, and also used for isolating an element such as an internal element of the semiconductor substrate 410 and the capacitor above on the other hand. A forming process of the bottom support layer 600 may also be a thermal oxidation process. Materials of the bottom support layer 600, the intermediate support layer 601 and the top support layer 602 include but not limited to the silicon nitride, materials of the first sacrificial layer 611 and the second sacrificial layer 612 include but not limited to the silicon oxide. In other embodiments of the disclosure, in order to support the bottom electrode layer better, more than two layers of the intermediate support layers 601 may also be stacked between the bottom support layer 600 and the top support layer 602. Optionally, all of the capacitors 705 can be arranged in hexagonal close packing. Further, the bottom electrode layer 701 is a cylinder-shaped structure, and can be a polysilicon electrode or a metal electrode. While the bottom electrode layer 701 is the metal electrode, a titanium nitride (TIN) and Ti stacked structure may also be used. While the bottom electrode layer 701 is the polysilicon electrode, it can be formed by using a zero-doped and/or doped polysilicon material. The capacitance dielectric layer 702 covers an inner surface and an outer surface of the cylinder-shaped structure of the bottom electrode layer 701, as to adequately use the two opposite surfaces of the bottom electrode layer 701, and form a capacitor with a larger electrode surface area. Preferably, the capacitance dielectric layer 702 can be a high-K dielectric layer such as a metal oxide. Further, the capacitance dielectric layer 702 is a multi-layer structure, for example, a two-layer structure of hafnium oxide-zirconium oxide. The top electrode layer 703 can be a single-layer structure or may also be the multi-layer structure, while the top electrode layer 703 is the single-layer structure, for example, it is the polysilicon electrode, and it may also be the metal electrode, while the top electrode layer 703 is the metal electrode, for example, it can be formed by using the titanium nitride (TiN). The top electrode layer 703 may form the capacitor with the capacitance dielectric layer 702 and the bottom electrode layer 701 both inside the corresponding cylinder-shaped structure and outside the cylinder-shaped structure. In addition, in the fringe area (namely a boundary area of a capacitance hole array) of the core area I, because of the presence of the lateral support layer (namely the intermediate support layer 601 and the top support layer 602), the capacitance dielectric layer 702 and the top electrode layer 703 both have side wall structures with concave-convex uneven shapes, the side wall structures with the concave-convex uneven shapes correspond to the intermediate support layer 601 and the top support layer 602 outside the cylinder-shaped structures of the bottom electrode layer 701, so that a portion, located in the fringe area (namely the boundary area of the capacitance hole array) of the core area I, of the top electrode layer 703 corresponds to the intermediate support layer 601 and the top support layer 602 and is protruded in a direction away from the bottom electrode layer 701, so that the boundary of the capacitor array in the core area I is uneven. In addition, in the present embodiment, the capacitance dielectric layer 702 and the top electrode layer 703 are also successively extended for covering the surface of the bottom support layer 600 reserved in the peripheral area II, in addition, the surface of the top electrode layer 703 is also covered by a top electrode filling layer 704, and a gap between the top electrode layers 703 is filled with the top electrode filling layer 704, in other words, a gap between the neighboring cylinder-shaped structures is filled with the top electrode filling layer 704 and the above formed structure is covered. Preferably, a material of the top electrode filling layer 704 includes undoped or boron-doped polysilicon.

Please refer to FIG. 20, the disclosure further provides a semiconductor device manufactured by using the above manufacturing method for the semiconductor device, including: a semiconductor substrate 410, an interlayer dielectric layer 500 and multiple contact plugs CP. The semiconductor substrate 410 has a core area I, a peripheral area II and a boundary area III located between the core area I and the peripheral area II, a shallow-groove isolation structure 411b for defining each AA1 is formed in the core area I, and a shallow-groove isolation structure 411a for defining the core area I and the peripheral area II is formed in the boundary area III. The interlayer dielectric layer 500 is formed on the semiconductor substrate 410, and can be a silicon dioxide, a silicon nitride or a low-K medium (a dielectric constant is less than 3). The multiple contact plugs CPs are formed in the interlayer dielectric layer 500, and in contact with the AA1 of the corresponding core element. There is no contact plug above a part of the AA1s at the boundary of the core area I. In addition, in some embodiments, the contact plugs CPs at the boundary of two opposite sides of the core area I are asymmetrically distributed, for example, the contact plugs at the upper side boundary and the lower side boundary of the core area I are asymmetrically distributed, and/or, the contact plugs at the left side boundary and the right side boundary of the core area I are asymmetrically distributed.

Optionally, the semiconductor device can be a memory, and it also includes multiple WLs, source area and drain area SID, a BL contact portion (unshown) and multiple BLs (unshown). Each WL is a buried-type word line, formed in the semiconductor substrate 410, and intersected with the AA1. The source area and drain area S/D are formed in the AA1s at two sides of the word line. The BL contact portion is formed in the drain area, and each BL is formed on the corresponding BL contact portion and intersected with each word line. The semiconductor substrate 410, the WLs, the source area and drain area S/D, the BL contact portion and the BLs are internally buried in the interlayer dielectric layer 500. At the boundary of the core area I, there is no contact plug above a part of the AAs between at least two outermost BLs, and/or (either or both), there is no contact plug above a part of the AAs between at least two WLs.

In conclusion, in the technical scheme of the disclosure, a forming position of the contact plug is defined by the mask plate combination provided by the disclosure, so that there is no contact plug above a part of the AAs at the boundary of the core area, and there are the contact plugs above the other AAs at the boundary of the core area and the AAs in the interior of the core area, therefore, while an existing process is used to form the corresponding electrical structures in the interior and boundary of the core area subsequently, a part of the electrical structures at the boundary of the core area become into the virtual structures because there is no contact plug in contact with the AA below the electrical structures, thereby a problem that the manufactured semiconductor device may not pass a relevant test due to a problem of the electrical structures at the boundary of the core area can be avoided, and performance and pass rate of the manufactured semiconductor device are improved.

It is to be noted that various embodiments in the description are described in a progressive mode, and each embodiment focuses on differences from other embodiments, and the same or similar portions between the various embodiments can be referred to each other. Furthermore, the above description is only a description of the preferred embodiments of the disclosure, and is not intended to limit a scope of the disclosure in any way, any changes and modifications made by those of ordinary skill in the art of the disclosure according to the above disclosed content shall fall within a scope of protection required by the technical scheme of the disclosure.

In addition, it is also to be noted that unless otherwise specified or pointed out, terms “first”, “second” and “third” and the like in the description are only used to distinguish various components, elements, operations and the like in the description, and are not used to represent a logical relation or a sequence relation and the like between the various components, the elements and the operations. A term “and/or” in the text means either or both.

1. An electrical contact structure of a semiconductor device, wherein the semiconductor device comprises a substrate, the substrate comprises a core area, a peripheral area and a boundary area located between the core area and the peripheral area, an isolation structure is formed in the boundary area, multiple core elements are formed in the core area, each of the multiple core elements comprises an active area (AA), the electrical contact structure comprises:
multiple contact plugs, formed above the core area and the isolation structure;
wherein, the multiple contact plugs comprise a first contact plug closest to the peripheral area, at least the first contact plug is formed above the isolation structure and in contact with the isolation structure, and the rest contact plugs are formed above each of the core elements in the core area and a bottom portion of each of the rest contact plugs is in contact with the AA of a corresponding core element.

2. The electrical contact structure of the semiconductor device as claimed in claim 1, wherein a bottom portion of the first contact plug is completely overlapped on the isolation structure.

3. The electrical contact structure of the semiconductor device as claimed in claim 1, wherein a part of a bottom portion of the first contact plug is overlapped on the isolation structure, and the other part of the bottom portion of the first contact plug is overlapped on the AA of the core element closest to the isolation structure.

4. The electrical contact structure of the semiconductor device as claimed in claim 1, wherein a bottom portion of the first contact plug is stretched into an interior of the isolation structure.

5. The electrical contact structure of the semiconductor device as claimed in claim 4, wherein a depth of the bottom portion of the first contact plug stretched into the interior of the isolation structure is less than a depth of the bottom portion of each of the rest contact plugs stretched into a corresponding AA.

6. The electrical contact structure of the semiconductor device as claimed in claim 1, wherein at least one gate electrode is buried in the substrate, and only one side of the first contact plug is in contact with the nearest neighboring gate electrode of the first contact plug buried in the substrate.

7. The electrical contact structure of the semiconductor device as claimed in claim 1, wherein the first contact plug is connected with a top portion of at least one of the nearest neighboring contact plugs of the first contact plug, and the at least one of the nearest neighboring contact plugs is formed above the core area.

8. The electrical contact structure of the semiconductor device as claimed in claim 7, wherein all of the multiple contact plugs of which top portions are connected together form an inverted U-shaped electrical contact structure or a comb-shaped electrical contact structure.

9. The electrical contact structure of the semiconductor device as claimed in claim 1, wherein the electrical contact structure further comprises multiple mutually independent contact pads, and are formed on a top portion of each of the rest contact plugs, and each of the contact pads is electrically connected with the top portion of a corresponding contact plug in one-to-one correspondence.

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)
